(19) United States
(12) Patent Application Publication
(10) Pub. No.: US 2023/0244760 A1
(43) Pub. Date: Aug. 3, 2023

(54) Cognitive Process Foundation

(71) Applicant: Cognitive Scale, Inc., Austin, TX (US)

(72) Inventors: Steven Teleki, Cedar Park, TX (US); Matthew Sanchez, Austin, TX (US)

(21) Appl. No.: 17/682,714

(22) Filed: Feb. 28, 2022

Related U.S. Application Data
(60) Provisional application No. 63/304,965, filed on Jan. 31, 2022.

(51) Int. Cl. G06K 9/62; G06N 5/04; G06N 5/02

(52) U.S. Cl. CPC G06K 9/6254; G06N 5/04; G06N 5/022; G06K 9/6263

(57) ABSTRACT

A system, method, and computer-readable medium are disclosed for cognitive information processing. The cognitive information processing includes receiving data from a plurality of data sources; processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign; using the augmented intelligence campaign to generate cognitively processed insights; and, providing the cognitively processed insights to a destination, the destination comprising a cognitive application, the cognitive application enabling a user to interact with the cognitive insights.

### BACKGROUND OF THE INVENTION

### Field of the Invention

The present invention relates in general to the field of computers and similar technologies, and in particular to software utilized in this field. Still more particularly, it relates to a method, system and computer-usable medium for performing an augmented intelligence (AI) campaign operation.

### Description of the Related Art

In general, “big data” refers to a collection of datasets so large and complex that they become difficult to process using typical database management tools and traditional data processing approaches. These datasets can originate from a wide variety of sources, including computer systems, mobile devices, credit card transactions, television broadcasts, and medical equipment, as well as infrastructures associated with cities, sensor-equipped buildings and factories, and transportation systems. Challenges commonly associated with big data, which may be a combination of structured, unstructured, and semi-structured data, include its capture, curation, storage, search, sharing, analysis and visualization. In combination, these challenges make it difficult to efficiently process large quantities of data within tolerable time intervals.

Nonetheless, big data analytics hold the promise of extracting insights by uncovering difficult-to-discover patterns and connections, as well as providing assistance in making complex decisions by analyzing different and potentially conflicting options. As such, individuals and organizations alike can be provided new opportunities to innovate, compete, and capture value.

One aspect of big data is “dark data,” which generally refers to data that is either not collected, neglected, or underutilized. Examples of data that is not currently being collected includes location data prior to the emergence of companies such as Foursquare or social data prior to the advent of companies such as Facebook. An example of data that is being collected, but may be difficult to access at the right time and place, includes the side effects of certain spider bites while an affected individual is on a camping trip. As another example, data that is collected and available, but has not yet been productized or fully utilized, may include disease insights from population-wide healthcare records and social media feeds. As a result, a case can be made that dark data may in fact be of higher value than big data in general, especially as it can likely provide actionable insights when it is combined with readily-available data.

### SUMMARY OF THE INVENTION

In one embodiment the invention relates to a method for cognitive information processing, comprising: receiving data from a plurality of data sources; processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign; using the augmented intelligence campaign to generate cognitively processed insights; and, providing the cognitively processed insights to a destination, the destination comprising a cognitive application, the cognitive application enabling a user to interact with the cognitive insights.

In another embodiment the invention relates to a system comprising: a processor; a data bus coupled to the processor; and a non-transitory, computer-readable storage medium embodying computer program code, the non-transitory, computer-readable storage medium being coupled to the data bus, the computer program code interacting with a plurality of computer operations and comprising instructions executable by the processor and configured for: receiving data from a plurality of data sources; processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign; using the augmented intelligence campaign to generate cognitively processed insights; and, providing the cognitively processed insights to a destination, the destination comprising a cognitive application, the cognitive application enabling a user to interact with the cognitive insights.

In another embodiment the invention relates to a computer-readable storage medium embodying computer program code, the computer program code comprising computer executable instructions configured for: receiving data from a plurality of data sources; processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign; using the augmented intelligence campaign to generate cognitively processed insights; and, providing the cognitively processed insights to a destination, the destination comprising a cognitive application, the cognitive application enabling a user to interact with the cognitive insights.

### BRIEF DESCRIPTION OF THE DRAWINGS

The present invention may be better understood, and its numerous objects, features and advantages made apparent to those skilled in the art by referencing the accompanying drawings. The use of the same reference number throughout the several figures designates a like or similar element.

FIG. 1 depicts an exemplary client computer in which the present invention may be implemented;

FIG. 2 is a simplified block diagram of an augmented intelligence system (AIS);

FIG. 3 is a simplified block diagram of an AIS reference model;

FIG. 4 shows a simplified block diagram of components associated with a cognitive process foundation;

FIGS. 5a and 5b are a simplified process diagram showing the performance of cognitive process promotion operations;

FIGS. 6a and 6b are a simplified process flow showing the lifecycle of cognitive agents implemented to perform AIS operations;

FIG. 7 is a simplified process diagram showing phases of a cognitive process lifecycle;

FIGS. 8a through 8f show operations performed in certain phases of a cognitive process lifecycle;

FIG. 9 is a simplified process diagram showing phases of an augmented intelligence (AI) campaign lifecycle; and

FIGS. 10a through 10d show operations performed in certain phases of an AI campaign lifecycle.

### DETAILED DESCRIPTION

A method, system and computer-usable medium are disclosed for performing an augmented intelligence (AI) campaign operation. Certain aspects of the invention reflect an appreciation that augmented intelligence is not technically different from what is generally regarded as general artificial intelligence. However, certain aspects of the invention likewise reflect an appreciation that typical implementations of augmented intelligence are more oriented towards complementing, or reinforcing, the role human intelligence plays when discovering relationships and solving problems. Likewise, various aspects of the invention reflect an appreciation that certain advances in general AI approaches may provide different perspectives on how computers and software can participate in tasks that have previously been thought of being exclusive to humans.

Certain aspects of the invention reflect an appreciation that processes and applications employing AI models have become common in recent years. However, certain aspects of the invention likewise reflect an appreciation that known approaches to building, deploying, and maintaining such processes, applications and models at significant scale can be challenging. More particularly, various technical hurdles can prevent operational success in AI application development and deployment. As an example, empowering development teams to more easily develop AI systems and manage their end-to-end lifecycle can prove challenging.

Accordingly, certain aspects of the invention reflect an appreciation that the ability to orchestrate a pipeline of AI components in the context of an AI campaign, described in greater detail herein, would not only facilitate chained deployment of an AI system, but will likely reduce implementation intervals while simultaneously optimizing the use of human and computing resources. In particular, such an approach may be advantageous when it is agnostic to common application development platforms and database conventions. Likewise, certain aspects of the invention reflect that AI systems are generally complex. Accordingly, a repeatable approach that reduces the skill required to develop and deploy AI systems can assist in achieving scalability of AI initiatives.

The present invention may be a system, a method, and/or a computer program product. The computer program product may include a computer readable storage medium (or media) having computer readable program instructions thereon for causing a processor to carry out aspects of the present invention. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing.

A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

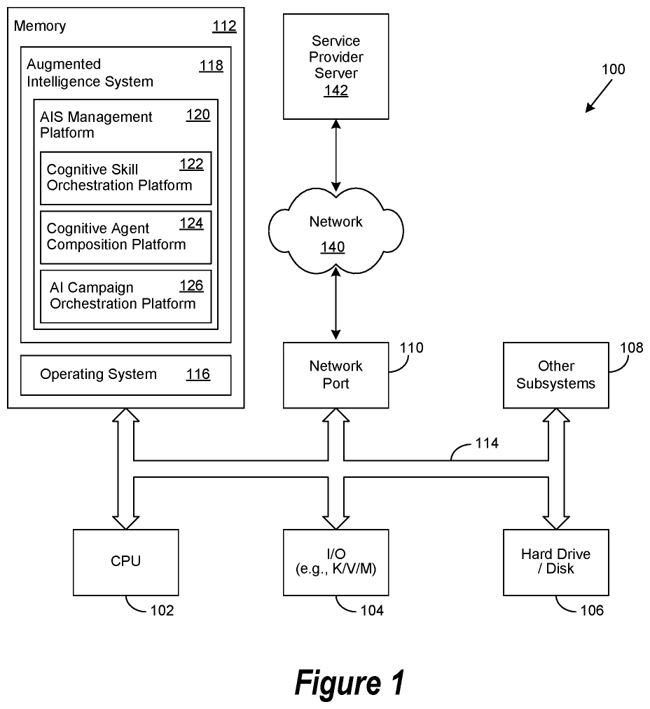

FIG. 1 is a generalized illustration of an information processing system 100 that can be used to implement the system and method of the present invention. The information processing system 100 includes a processor (e.g., central processor unit or “CPU”) 102, input/output (I/O) devices 104, such as a display, a keyboard, a mouse, a touchpad or touchscreen, and associated controllers, a hard drive or disk storage 106, and various other subsystems 108. In certain embodiments, the information processing system 100 may also include a network port 110 operable to connect to a network 140, which is likewise accessible by a service provider server 142. The information processing system 100 likewise includes system memory 112, which is interconnected to the foregoing via one or more buses 114. System memory 112 further comprises operating system (OS) 116 and in certain embodiments may also comprise an augmented intelligence system (AIS) 118. In these and other embodiments, the AIS 118 may likewise comprise an AIS management platform 120. In certain embodiments, the AIS management platform 120 may include a cognitive skill orchestration platform 122, a cognitive agent composition platform 124, and an augmented intelligence (AI) campaign orchestration platform 126, or a combination thereof. In certain embodiments, the information processing system 100 may be implemented to download the AIS 118 from the service provider server 142. In another embodiment, the functionality of the AIS 118 may be provided as a service from the service provider server 142.

In certain embodiments, the AIS 118 may be implemented to perform various cognitive computing operations. As used herein, cognitive computing broadly refers to a class of computing involving self-learning systems that use techniques such as spatial navigation, machine vision, and pattern recognition to increasingly mimic the way the human brain works. To be more specific, earlier approaches to computing typically solved problems by executing a set of instructions codified within software. In contrast, cognitive computing approaches are data-driven, sense-interpretation, insight-extracting, problem-solving, recommendation-making systems that have more in common with the structure of the human brain than with the architecture of contemporary, instruction-driven computers.

To further differentiate these distinctions, traditional computers must first be programmed by humans to perform specific tasks, while cognitive computing systems learn from their interactions with data and humans alike, and in a sense, program themselves to perform new tasks. To summarize the difference between the two, traditional computers are designed to calculate rapidly. In contrast, cognitive computing systems are designed to quickly draw inferences from data and gain new knowledge.

Cognitive computing systems achieve these abilities by combining various aspects of artificial intelligence, natural language processing, dynamic learning, and hypothesis generation to render vast quantities of intelligible data to assist humans in making better decisions. As such, cognitive computing systems can be characterized as having the ability to interact naturally with people to extend what either humans, or machines, could do on their own. Furthermore, they are typically able to process natural language, multi-structured data, and experience much in the same way as humans. Moreover, they are also typically able to learn a knowledge domain based upon the best available data and get better, and more immersive, over time.

It will be appreciated that more data is currently being produced every day than was recently produced by human beings from the beginning of recorded time. Deep within this ever-growing mass of data is a class of data known as “dark data,” which includes neglected information, ambient signals, and insights that can assist organizations and individuals in augmenting their intelligence and deliver actionable insights through the implementation of cognitive processes.

As used herein, a cognitive process broadly refers to an instantiation of one or more associated cognitive computing operations, described in greater detail herein. In certain embodiments, a cognitive process may be implemented as a cloud-based, big data interpretive process that learns from user engagement and data interactions. In certain embodiments, such cognitive processes may be implemented to extract patterns and insights from dark data sources that are currently almost completely opaque. Examples of dark data include disease insights from population-wide healthcare records and social media feeds, or from new sources of information, such as sensors monitoring pollution in delicate marine environments.

In certain embodiments, a cognitive process may be implemented to include a cognitive application. As used herein, a cognitive application broadly refers to a software application that incorporates one or more cognitive processes. In certain embodiments, a cognitive application may be implemented to incorporate one or more cognitive processes with other functionalities, as described in greater detail herein.

Over time, it is anticipated that cognitive processes and applications will fundamentally change the ways in which many organizations operate as they invert current issues associated with data volume and variety to enable a smart, interactive data supply chain. Ultimately, cognitive processes and applications hold the promise of receiving a user query and immediately providing a data-driven answer from a masked data supply chain in response. As they evolve, it is likewise anticipated that cognitive processes and applications may enable a new class of “sixth sense” processes and applications that intelligently detect and learn from relevant data and events to offer insights, predictions and advice rather than wait for commands. Just as web and mobile applications have changed the way people access data, cognitive processes and applications may change the way people consume, and become empowered by, multi-structured data such as emails, social media feeds, doctors notes, transaction records, and call logs.

However, the evolution of such cognitive processes and applications has associated challenges, such as how to detect events, ideas, images, and other content that may be of interest. For example, assuming that the role and preferences of a given user are known, how is the most relevant information discovered, prioritized, and summarized from large streams of multi-structured data such as news feeds, blogs, social media, structured data, and various knowledge bases? To further the example, what can a healthcare executive be told about their competitor's market share? Other challenges include the creation of a contextually-appropriate visual summary of responses to questions or queries.

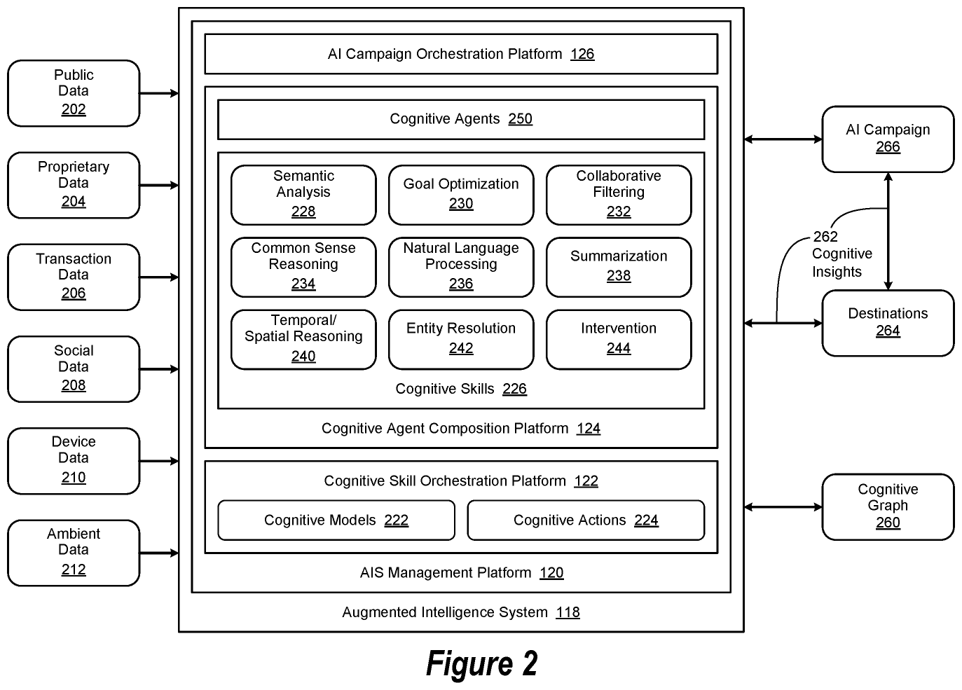

FIG. 2 is a simplified block diagram of an augmented intelligence system (AIS) implemented in accordance with an embodiment of the invention. As used herein, augmented intelligence broadly refers to an alternative conceptualization of general artificial intelligence oriented to its use in an assistive role, with an emphasis on the implementation of cognitive computing, described in greater detail herein, to enhance human intelligence rather than replace it. In certain embodiments, an AIS 118 may be implemented to include an AIS management platform 120.

In various embodiments, the AIS management platform 120 may be implemented to manage the performance of one or more cognitive computing operations, likewise described in greater detail herein. In certain of these embodiments, the one or more cognitive computing operations may be performed individually, sequentially, in parallel, in combination with one another, or a combination thereof. In certain embodiments, the AIS management platform 120 may be implemented to include a cognitive skill orchestration platform 122, a cognitive agent composition platform 124, and an AI campaign orchestration platform 126, or a combination thereof. In certain embodiments, the cognitive skill orchestration platform 122 may be implemented to orchestrate the use of a cognitive skill 226 using one or more cognitive models 222.

As used herein, a cognitive skill 226 broadly refers to the smallest distinct unit of functionality in a cognitive agent 250 that can be invoked by one or more inputs to produce one or more outputs. In certain embodiments, the inputs and outputs may include services, managed content, database connections, and so forth. In certain embodiments, cognitive skills 226 may be implemented to be connected via input/output units, or synapses, which control the flow of data through an associated cognitive agent 250.

In certain embodiments, a cognitive skill 226 may be implemented to include a definition identifying various dataset input requirements, cognitive insight 262 outputs, and datasets needed to complete the cognitive skill's 226 associated cognitive actions 224. In certain embodiments, an output of one cognitive skill 226 may be used as the input to another cognitive skill 226 to build complex cognitive agents 250. In various embodiments, certain cognitive skills 226 may be implemented to control the flow of data through an associated cognitive agent 250. In various embodiments, a cognitive skill 226 may be implemented as a modular entity to interface a particular cognitive agent 250 to certain external applications and Application Program Interfaces (APIs). In certain embodiments, a cognitive skill 226 may be implemented to perform extract, transform, load (ETL) operations upon the output of another cognitive skill 226, thereby serving as a wrapper for an ML classifier or regressor.

A cognitive agent 250, as likewise used herein, broadly refers to a computer program that performs a task with minimal guidance from users and learns from each interaction with data and human users. As used herein, as it relates to a cognitive agent 250 performing a particular task, minimal guidance broadly refers to the provision of non-specific guidelines, parameters, objectives, constraints, procedures, or goals, or a combination thereof, for the task by a user. For example, a user may provide specific guidance to a cognitive agent 250 by asking, “How much would I have to improve my body mass index (BMI) to lower my blood pressure by twenty percent?” Conversely, a user may provide minimal guidance to the cognitive agent 250 by asking, “Given the information in my current health profile, what effect would improving my BMI have on my overall health?”

Likewise, as used herein, a cognitive model 222 broadly refers to a machine learning model that serves as a mathematical representation of a real-world process that can be facilitated by a cognitive computing operation. In certain embodiments, the implementation of a cognitive model 222 may involve the implementation of one or more cognitive actions 224. As likewise used herein, a cognitive action 224 broadly refers to how a cognitive skill performs a particular cognitive model's 222 intended purpose.

In certain embodiments, a cognitive action 224 may be implemented as a function, a batch job, or a daemon, all of which will be familiar to skilled practitioners of the art. In various embodiments, a cognitive action 224 implemented as a batch job may be configured to run at certain intervals or be triggered to run when a certain event takes place. In certain embodiments, cognitive actions 224 may be implemented to be decoupled from a particular cognitive skill 226 such that they may be reused by other cognitive skills 226. In certain embodiments, a first cognitive action 224 may be implemented to train a particular cognitive model 222 and a second cognitive action 224 may be implemented to make predictions based upon a set of unlabeled data to provide a cognitive insight 262, described in greater detail herein.

In various embodiments, the cognitive agent composition platform 124 may be implemented to use certain cognitive skills 226, input/output services, datasets, and data flows, or a combination thereof, to compose a particular cognitive agent 250. In certain embodiments, one or more cognitive skills 226 may be implemented to provide various disjointed functionalities within a particular cognitive agent 250. In certain embodiments, such functionalities may include ingesting, enriching, and storing data from a data stream, training and testing a machine learning (ML) algorithm to generate an ML model, and loading data from an external source, such as a file. In certain embodiments, such functionalities may likewise include transforming the raw data into a dataset for further processing, extracting features from a dataset, or invoking various services, such as web services familiar to those of skill in the art.

In certain embodiments, a cognitive agent 250 may be composed from other cognitive agents 250 to create new functionalities. In certain embodiments, a cognitive agent 250 may be implemented to expose its functionality through a web service, which can be used to integrate it into a cognitive process or application, described in greater detail herein. In certain embodiments, cognitive agents 250 may be implemented to ingest various data, such as public 202, proprietary 204, transaction, social 208, device 210, and ambient 212 data, to provide a cognitive insight 262 or make a recommendation.

In certain embodiments, a cognitive agent 250 may be implemented with an integration layer. In certain embodiments, the integration layer may be implemented to provide data to a particular cognitive agent 250 from various data sources, services, such as a web service, other cognitive agents 250, or a combination thereof. In certain embodiments, the integration layer may be implemented to provide a user interface (UI) to a cognitive agent 250. In certain embodiments, the UI may include a web interface, a mobile device interface, or stationary device interface.

In certain embodiments, one or more cognitive agents 250 may be managed by the AIS management platform 120 to generate one or more cognitive insights 262. In certain embodiments, one or more cognitive agents 250 may be implemented as deployable modules that aggregate the logic, data and models required to perform one or more cognitive computing operations. In certain embodiments, a particular cognitive agent 250 may be implemented to be triggered by other cognitive agents 250, timers, or by external requests.

As used herein, an input/output service broadly refers to a live link that is implemented to send and receive data. In certain embodiments, input/output services may be defined in input/output pairs that require and deliver a payload to and from a cognitive agent 250. In certain embodiments, public 202, proprietary 204, transaction, social 208, device 210, and ambient 212 data may be ingested and processed by the AIS 118 to generate one or more datasets. As used herein, a dataset broadly refers to a type of data input a cognitive agent 250 may be implemented to ingest. In certain embodiments, such a dataset may be implemented to include a definition that includes the source of the data and its corresponding schema.

Various embodiments of the invention reflect an appreciation that the implementation of certain cognitive skills 226 may streamline, or otherwise facilitate, the construction of certain cognitive agents 250. In various embodiments, certain cognitive skills 226 may be implemented as micro services and published in a repository of AIS components, described in greater detail herein, as ready-to-use units, which can be mixed and matched between cognitive computing projects. Certain embodiments of the invention reflect an appreciation that the ability to adopt an assembly model that supports the mixing and matching of cognitive skills 226 between cognitive computing projects may minimize the effort required to rewrite code for new cognitive agents 250, and by extension, shorten development cycles.

As shown in FIG. 2, examples of cognitive skills 226 used by the cognitive agent composition platform 124 to generate cognitive agents 250 include semantic analysis 228, goal optimization 230, collaborative filtering 232, and common sense reasoning 234. Other examples of such cognitive skills 226 include natural language processing 236, summarization 238, temporal/spatial reasoning 240, entity resolution 242, and intervention 244. As used herein, semantic analysis broadly refers to performing various analysis operations to achieve a semantic level of understanding about language by relating syntactic structures.

In certain embodiments, various syntactic structures may be related from the levels of phrases, clauses, sentences, and paragraphs to the level of the body of content as a whole, and to its language-independent meaning. In certain embodiments, the semantic analysis 228 cognitive skill may include processing a target sentence to parse it into its individual parts of speech, tag sentence elements that are related to certain items of interest, identify dependencies between individual words, and perform co-reference resolution. For example, if a sentence states that the author really enjoys the hamburgers served by a particular restaurant, then the name of the “particular restaurant” is co-referenced to “hamburgers.”

As likewise used herein, goal optimization broadly refers to performing multi-criteria decision making operations to achieve a given goal or target objective. In certain embodiments, one or more goal optimization 230 cognitive skills 226 may be used by the cognitive agent composition platform 124 to generate a cognitive agent 250 for defining predetermined goals, which in turn contribute to the generation of an associated cognitive insight 262. For example, goals for planning a vacation trip may include low cost (e.g., transportation and accommodations), location (e.g., by the beach), and speed (e.g., short travel time). In this example, it will be appreciated that certain goals may be in conflict with another. As a result, a cognitive insight 262 provided by the AIS 118 to a traveler may indicate that hotel accommodations by a beach may cost more than they care to spend.

Collaborative filtering, as used herein, broadly refers to the process of filtering for information or patterns through the collaborative involvement of multiple cognitive agents, viewpoints, data sources, and so forth. In certain embodiments, the application of such collaborative filtering 232 cognitive skills may involve very large and different kinds of data sets, including sensing and monitoring data, financial data, and user data of various kinds. In certain embodiments, collaborative filtering may also refer to the process of making automatic predictions associated with predetermined interests of a user by collecting preferences or other information from many users. For example, if person ‘A’ has the same opinion as a person ‘B’ for a given issue ‘x’, then an assertion can be made that person ‘A’ is more likely to have the same opinion as person ‘B’ opinion on a different issue ‘y’ than to have the same opinion on issue ‘y’ as a randomly chosen person. In certain embodiments, the collaborative filtering 206 cognitive skill may be implemented with various recommendation engines familiar to those of skill in the art to make recommendations.

As used herein, common sense reasoning broadly refers to simulating the human ability to make deductions from common facts they inherently know. Such deductions may be made from inherent knowledge about the physical properties, purpose, intentions and possible behavior of ordinary things, such as people, animals, objects, devices, and so on. In various embodiments, certain common sense reasoning 234 cognitive skills may be composed by the cognitive agent composition platform 120 to generate a cognitive agent 250 that assists the AIS 118 in understanding and disambiguating words within a predetermined context. In certain embodiments, the common sense reasoning 234 cognitive skill may be used by the cognitive agent composition platform 120 to generate a cognitive agent 250 that allows the AIS 118 to generate text or phrases related to a target word or phrase to perform deeper searches for the same terms. It will be appreciated that if the context of a word is better understood, then a common sense understanding of the word can then be used to assist in finding better or more accurate information. In certain embodiments, the better or more accurate understanding of the context of a word, and its related information, allows the AILS 118 to make more accurate deductions, which are in turn used to generate cognitive insights 262.

As likewise used herein, natural language processing (NLP) broadly refers to interactions with a system, such as the AIS 118, through the use of human, or natural, languages. In certain embodiments, various NLP 210 cognitive skills may be implemented by the AIS 118 to achieve natural language understanding, which enables it to not only derive meaning from human or natural language input, but to also generate natural language output.

Summarization, as used herein, broadly refers to processing a set of information, organizing and ranking it, and then generating a corresponding summary. As an example, a news article may be processed to identify its primary topic and associated observations, which are then extracted, ranked, and presented to the user. As another example, page ranking operations may be performed on the same news article to identify individual sentences, rank them, order them, and determine which of the sentences are most impactful in describing the article and its content. As yet another example, a structured data record, such as a patient's electronic medical record (EMR), may be processed using certain summarization 238 cognitive skills to generate sentences and phrases that describes the content of the EMR. In certain embodiments, various summarization 238 cognitive skills may be used by the cognitive agent composition platform 120 to generate to generate a cognitive agent 250 that provides summarizations of content streams, which are in turn used by the AIS 118 to generate cognitive insights 262.

As used herein, temporal/spatial reasoning broadly refers to reasoning based upon qualitative abstractions of temporal and spatial aspects of common sense knowledge, described in greater detail herein. For example, it is not uncommon for a particular set of data to change over time. Likewise, other attributes, such as its associated metadata, may also change over time. As a result, these changes may affect the context of the data. To further the example, the context of asking someone what they believe they should be doing at 3:00 in the afternoon during the workday while they are at work may be quite different than asking the same user the same question at 3:00 on a Sunday afternoon when they are at home. In certain embodiments, various temporal/spatial reasoning 214 cognitive skills may be used by the cognitive agent composition platform 120 to generate a cognitive agent 250 for determining the context of queries, and associated data, which are in turn used by the AIS 118 to generate cognitive insights 262.

As likewise used herein, entity resolution broadly refers to the process of finding elements in a set of data that refer to the same entity across different data sources (e.g., structured, non-structured, streams, devices, etc.), where the target entity does not share a common identifier. In certain embodiments, various entity resolution 216 cognitive skills may be used by the cognitive agent composition platform 120 to generate a cognitive agent 250 that can be used to identify significant nouns, adjectives, phrases or sentence elements that represent various predetermined entities within one or more domains. From the foregoing, it will be appreciated that the use of one or more of the semantic analysis 228, goal optimization 230, collaborative filtering 232, common sense reasoning 234, natural language processing 236, summarization 238, temporal/spatial reasoning 240, and entity resolution 240 cognitive skills by the cognitive agent composition platform 124 can facilitate the generation of a semantic, cognitive model. An intervention, as it relates to a cognitive skill 226, broadly refers to an action associated with a particular mission, described in greater detail herein, that is in turn associated with a particular cognitive agent 250 implemented as part of an AI campaign 266.

In certain embodiments, the AIS 118 may receive public 202, proprietary 204, transaction, social 208, device 210, and ambient 212 data, or a combination thereof, which is then processed by the AIS 118 to generate one or more cognitive graphs 230. As used herein, public 202 data broadly refers to any data that is generally available for consumption by an entity, whether provided for free or at a cost. As likewise used herein, proprietary 204 data broadly refers to data that is owned, controlled, or a combination thereof, by an individual user, group, or organization, which is deemed important enough that it gives competitive advantage to that individual or organization. In certain embodiments, the organization may be a governmental, non-profit, academic or social entity, a manufacturer, a wholesaler, a retailer, a service provider, an operator of an AIS 118, and others. In certain embodiments, the public data 202 and proprietary 204 data may include structured, semi-structured, or unstructured data.

As used herein, transaction 206 data broadly refers to data describing an event, and is usually described with verbs. In typical usage, transaction data includes a time dimension, a numerical value, and certain reference data, such as references to one or more objects. In certain embodiments, the transaction 206 data may include credit or debit card transaction data, financial services data of all kinds (e.g., mortgages, insurance policies, stock transfers, etc.), purchase order data, invoice data, shipping data, receipt data, or any combination thereof. In certain embodiments, the transaction data 206 may include blockchain-associated data, smart contract data, or any combination thereof. Skilled practitioners of the art will realize that many such examples of transaction 206 data are possible. Accordingly, the foregoing is not intended to limit the spirit, scope or intent of the invention.

As used herein, social 208 data broadly refers to information that social media users publicly share, which may include metadata such as the user's location, language spoken, biographical, demographic or socio-economic information, and shared links. As likewise used herein, device 210 data broadly refers to data associated with, or generated by, an apparatus. Examples of device 210 data include data associated with, or generated by, a vehicle, home appliance, security systems, and so forth, that contain electronics, software, sensors, actuators, and connectivity, or a combination thereof, that allow the collection, interaction and provision of associated data.

As used herein, ambient 212 data broadly refers to input signals, or other data streams, that may contain data providing additional insight or context to public 202, proprietary 204, transaction 206, social 208, and device 210 data received by the AIS 118. For example, ambient signals may allow the AIS 118 to understand that a user is currently using their mobile device, at location ‘x,’ at time ‘y,’ doing activity ‘z.’ To continue the example, there is a difference between the user using their mobile device while they are on an airplane versus using their mobile device after landing at an airport and walking between one terminal and another.

To extend the example, ambient 212 data may add additional context, such as the user is in the middle of a three leg trip and has two hours before their next flight. Further, they may be in terminal A1, but their next flight is out of C1, it is lunchtime, and they want to know the best place to eat. Given the available time the user has, their current location, restaurants that are proximate to their predicted route, and other factors such as food preferences, the AIS 118 can perform various cognitive operations and provide a cognitive insight 262 that includes a recommendation for where the user can eat.

To extend the example even further, the user may receive a notification while they are eating lunch at a recommended restaurant that their next flight has been canceled due to the previously-scheduled aircraft being grounded. As a result, the user may receive two cognitive insights 262 suggesting alternative flights on other carriers. The first cognitive insight 262 may be related to a flight that leaves within a half hour. The second cognitive insight 262 may be related to a second flight that leaves in an hour but requires immediate booking and payment of additional fees. Knowing that they would be unable to make the first flight in time, the user elects to use the second cognitive insight 262 to automatically book the flight and pay the additional fees through the use of a digital currency transaction.

In certain embodiments, the AIS 118 may be implemented to represent knowledge in the cognitive graph 260, such that the knowledge can be used to perform reasoning and inference operations. In certain embodiments, the resulting reasoning and inference operations may be implemented to provide self-assurance. Accordingly, such approaches may be implemented in certain embodiments as a cognitive inference and learning system (CILS). In certain embodiments, the self-assurance resulting from such reasoning and inference operations may be implemented to provide cognitive insights 262 with associated explainability. In these embodiments, such explainability may be implemented to provide a rationale for their associated cognitive insights 262. As used herein, as it relates to explainability, described in greater detail herein, rationale broadly refers to an explanation of the basis, or the set of reasons, or a combination thereof, used to generate a particular cognitive insight 262.

As used herein, a cognitive graph 260 refers to a representation of expert knowledge, associated with individuals and groups over a period of time, to depict relationships between people, places, and things using words, ideas, audio and images. As such, it is a machine-readable formalism for knowledge representation that provides a common framework allowing data and knowledge to be shared and reused across user, application, organization, and community boundaries. In various embodiments, the information contained in, and referenced by, a cognitive graph 260 may be derived from many sources, such as public 202, proprietary 204, transaction, social 208, device 210, and ambient 212 data, or a combination thereof. In certain of these embodiments, the cognitive graph 260 may be implemented to assist in the identification and organization of information associated with how people, places and things are related to one other. In various embodiments, the cognitive graph 260 may be implemented to enable automated cognitive agents 250, described in greater detail herein, to access the Web more intelligently, enumerate inferences through utilization of various data sources, and provide answers to questions by serving as a computational knowledge engine.

In certain embodiments, the cognitive graph 260 may be implemented to not only elicit and map expert knowledge by deriving associations from data, but to also render higher level insights and accounts for knowledge creation through collaborative knowledge modeling. In certain embodiments, the cognitive graph 260 may be implements as a machine-readable, declarative memory system that stores and learns both episodic memory (e.g., specific personal experiences associated with an individual or entity), and semantic memory, which stores factual information (e.g., geo location of an airport or restaurant).

For example, the cognitive graph 260 may know that a given airport is a place, and that there is a list of related places such as hotels, restaurants and departure gates. Furthermore, the cognitive graph 260 may know that people such as business travelers, families and college students use the airport to board flights from various carriers, eat at various restaurants, or shop at certain retail stores. The cognitive graph 260 may also have knowledge about the key attributes from various retail rating sites that travelers have used to describe the food and their experience at various venues in the airport over the past six months.

In certain embodiments, the AI campaign orchestration platform 126 may be implemented to perform an AI campaign operation. As used herein, an AI campaign operation broadly refers to a cognitive process, described in greater detail herein, that is performed in the context of an AI campaign 266, likewise described in greater detail herein. In various embodiments, the AI campaign orchestration platform 126 may be implemented to orchestrate certain cognitive agents 250 to generate one or more cognitive insights 262.

In certain embodiments, the resulting cognitive insights 262 may be delivered to one or more destinations 264, described in greater detail herein. As used herein, a cognitive insight 262 broadly refers to an actionable, real-time recommendation tailored to a particular user, as described in greater detail herein. Examples of such recommendations include getting an immunization, correcting a billing error, taking a bus to an appointment, considering the purchase of a particular item, selecting a recipe, eating a particular food item, and so forth.

In certain embodiments, cognitive insights 262 may be generated from various data sources, such as public 202, proprietary 204, transaction, social 208, device 210, and ambient 212 data, a cognitive graph 260, or a combination thereof. For example, if a certain percentage of the population in a user's community is suffering from the flu, then the user may receive a recommendation to get a flu shot. In this example, determining the afflicted percentage of the population, or determining how to define the community itself, may prove challenging. Accordingly, generating meaningful insights or recommendations may be difficult for an individual user, especially when related datasets are large.

In various embodiments, one or more cognitive insights 262 resulting from the implementation of a particular AI campaign 266 may be delivered to one or more destinations 264. In certain embodiments, a resulting cognitive insight 262 stream may be implemented to be bidirectional, supporting flows of information both too and from various destinations 264, or a particular AI campaign 266, or both. In these embodiments, a first flow of cognitive insights 262 may be generated in response to receiving a query, and subsequently delivered to one or more destinations 264, or a particular AI campaign 266, or both. Likewise, a second flow of cognitive insights 262 may be generated in response to detecting information about a user of one or more of the destinations 264, or a particular AI campaign 266, or both.

Such use may result in the provision of information to the AIS 118. In response, the AIS 118 may process that information, in the context of what it knows about the user, and provide additional information to the user, such as a recommendation. In certain embodiments, a stream of cognitive insights 262 may be configured to be provided in a “push” stream configuration familiar to those of skill in the art. In certain embodiments, a stream of cognitive insights 262 may be implemented to use natural language approaches familiar to skilled practitioners of the art to support interactions with a user.

In certain embodiments, a stream of cognitive insights 262 may be implemented to include a stream of visualized insights. As used herein, visualized insights broadly refer to cognitive insights that are presented in a visual manner, such as a map, an infographic, images, and so forth. In certain embodiments, these visualized insights may include various cognitive insights, such as “What happened?” “What do I know about it?” “What is likely to happen next?” or “What should I do about it?” In these embodiments, the stream of cognitive insights 262 may be generated by various cognitive agents 250, which are applied to various sources, datasets, and cognitive graphs.

In certain embodiments, the AIS 118 may be implemented to deliver Cognition as a Service (CaaS). As such, it provides a cloud-based development and execution platform that allow various cognitive applications and services to function more intelligently and intuitively. In certain embodiments, cognitive applications powered by the AIS 118 are able to think and interact with users as intelligent virtual assistants. As a result, users are able to interact with such cognitive applications by asking them questions and giving them commands. In response, these cognitive applications will be able to assist the user in completing tasks and managing their work more efficiently.

In these and other embodiments, the AIS 118 may be implemented to operate as an analytics platform to process big data, and dark data as well, to provide data analytics through a public, private or hybrid cloud environment, described in greater detail herein. As used herein, cloud analytics broadly refers to a service model wherein data sources, data models, processing applications, computing power, analytic models, and sharing or storage of results are implemented within a cloud environment to perform one or more aspects of analytics.

In certain embodiments, users may submit queries and computation requests in a natural language format to the AIS 118. In response, they are provided with a ranked list of relevant answers and aggregated information with useful links and pertinent visualizations through a graphical representation. In these embodiments, the cognitive graph 230 may be implemented to generate semantic and temporal maps to reflect the organization of unstructured data and to facilitate meaningful learning from potentially millions of lines of text, much in the same way as arbitrary syllables strung together create meaning through the concept of language.

In certain embodiments, the AIS 118 may be implemented to represent knowledge in the cognitive graph 260, such that the knowledge can be used to perform reasoning and inference operations. In certain embodiments, the resulting reasoning and inference operations may be implemented to provide self-assurance. Accordingly, such approaches may be implemented in certain embodiments as a cognitive inference and learning system (CILS). In certain embodiments, the self-assurance resulting from such reasoning and inference operations may be implemented to provide cognitive insights with associated explainability. In these embodiments, such explainability may be implemented to provide a rationale for their associated cognitive insights.

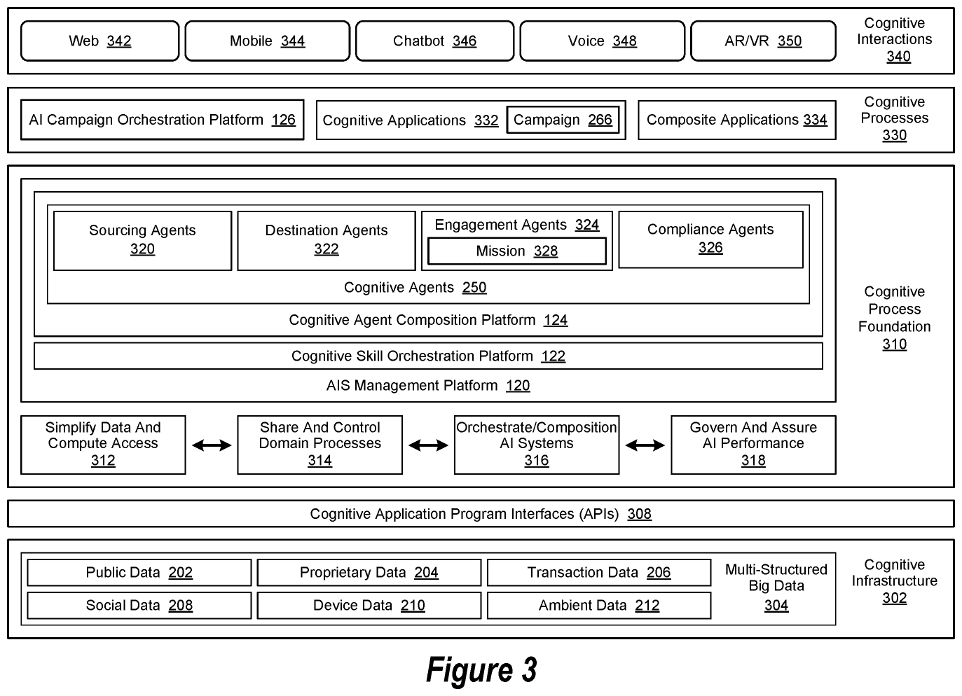

FIG. 3 is a simplified block diagram of an augmented intelligence system (AIS) reference model implemented in accordance with an embodiment of the invention. In various embodiments, the AIS reference model shown in FIG. 3 may be implemented as a reference for certain components included in, and functionalities performed by, an AIS, described in greater detail herein. In certain embodiments, these components and functionalities may include a cognitive infrastructure 302, one or more cognitive Application Program Interfaces (APIs) 308, a cognitive process foundation 310, various cognitive processes 330, and various cognitive interactions 340.

In certain embodiments, the cognitive infrastructure 302 may include various sources of multi-structured big data 304. In certain embodiments, the sources of multi-structured big data 304 may include repositories of public 202, proprietary 204, transaction 206, social 208, device 210, and ambient 212 data, or some combination thereof. In certain embodiments, the repositories of transaction data 206 may include blockchain data associated with one or more public blockchains, one or more private blockchains, or a combination thereof. In certain embodiments, the repositories of transaction data 206 may be used to generate a blockchain-associated cognitive insight. In various embodiments, the cognitive APIs 308 may be implemented for use by the AIS management platform 120, described in greater detail herein, to access certain cognitive infrastructure 302 components.

In various embodiments, the cognitive process foundation 310, likewise described in greater detail herein, may be implemented to provide certain cognitive computing functionalities. In certain embodiments, these cognitive computing functionalities may include the simplification of data and compute resource access 312. In certain embodiments, these cognitive computing functionalities may likewise include various sharing and control 314 operations commonly associated with domain processes. Likewise, in certain embodiments these cognitive computing functionalities may include the orchestration and composition 316 of various artificial intelligence systems.

In certain embodiments, the orchestration and composition 316 of various AI systems may include the orchestration of cognitive skills and the composition of cognitive agents, as described in greater detail herein. In certain embodiments, the orchestration and composition 316 functionalities may include the orchestration of various cognitive skills and the composition of cognitive agents, and associated AIS components, to generate one or more cognitive processes 330, likewise described in greater detail herein.

In certain embodiments, these cognitive computing functionalities may include AI governance and assurance 318 operations associated with ensuring the integrity and transparency of an AI system in the context of various cognitive computing operations it may perform. As used herein, AI governance broadly refers to the management of the availability, consistency, integrity, usability, security, privacy, and compliance of data and processes used to perform a cognitive computing operation, described in greater detail herein. Certain embodiments of the invention reflect an appreciation that practices and processes associated with AI governance ideally provide an effective foundation, strategy, and framework to ensure that data can be managed as an asset and transformed into meaningful information as a result of a cognitive computing operation. Certain aspects of the invention likewise reflect an appreciation that implementation of various AI governance programs may include a governing body or council, a defined set of procedures, and a plan to execute those procedures.

Certain embodiments of the invention reflect an appreciation that AI governance typically includes other concepts, such as data stewardship and data quality, which may be used to improve control over various components of an AIS. In various embodiments, certain AI governance and assurance 318 operations may be implemented to improve control over other components of the cognitive process foundation 310. In these embodiments, the AI governance and assurance 318 operations may be implemented to improve control over the simplification of data and compute access 312, sharing and controlling domain processes 314, and orchestrating and composing AI systems 316.

In certain embodiments, the AI governance and assurance 318 operations may likewise be implemented to improve control over a cognitive infrastructure 302, cognitive APIs 308, cognitive processes 330, and cognitive interactions 340. Various embodiments of the invention reflect an appreciation that improving control over such components of an AIS may include certain methods, technologies, and behaviors, described in greater detail herein. Likewise, various embodiments of the invention reflect an appreciation that effective AI governance generally involves the exercise of authority and control (e.g., planning, monitoring, enforcement, etc.) over the management of AIS components used in the performance of certain cognitive computing operation.

Furthermore, certain embodiments of the invention reflect an appreciation that the lack of adequate AI governance may result in poor data quality. Moreover, various embodiments of the invention reflect an appreciation that the lack of adequate AI governance may result in poor, unexpected, or otherwise undesirable performance of certain cognitive skills and cognitive agents, described in greater detail herein. Accordingly, various embodiments of the invention likewise reflect an appreciation that poor data quality, unexpected or otherwise undesirable performance of certain cognitive skills and cognitive agents, or a combination thereof, may have an adverse effect upon the results of an associated cognitive computing operation.

As likewise used herein, AI assurance broadly refers to ensuring the transparency, interpretability, impartiality, accountability, and trustworthiness of the cognitive computing operations an AIS performs to produce a resulting outcome, such as a cognitive insight, described in greater detail herein. Certain embodiments of the invention reflect an appreciation that practices and processes associated with AI assurance generally provide an effective foundation, strategy, and framework to ensure that an AIS can perform its intended function free from deliberate or inadvertent manipulation. Certain embodiments of the invention reflect an appreciation that such practices and processes can likewise assist in ensuring cognitive computing operations performed by an AIS adhere to its operational and technical parameters within prescribed limits. In certain embodiments, various cognitive computing functionalities may be implemented to work individually, or in concert with one another. In these embodiments, the method by which these various cognitive computing functionalities are implemented is a matter of design choice.

As likewise shown in FIG. 3, the cognitive process foundation 310 may be implemented in certain embodiments to include an AIS management platform 120. In certain embodiments, the AIS management platform may in turn be implemented in certain embodiments to include a cognitive skill orchestration platform 122, or a cognitive agent composition platform 124, or both. In certain embodiments, the cognitive agent composition platform 124 may be implemented to compose one or more cognitive agents 250. In certain embodiments, the cognitive agents 250 may include a sourcing agent 320, a destination agent 322, an engagement agent 324, a compliance agent 326, or a combination thereof. In certain embodiments, the sourcing agent 320 may be implemented to source a variety of multi-site, multi-structured source streams of data described in greater detail herein.

In various embodiments, the destination agent 324 may be implemented to publish cognitive insights to a consumer of cognitive insight data. Examples of such consumers of cognitive insight data include target databases, public or private blockchains, business intelligence applications, and mobile applications. It will be appreciated that many such examples of cognitive insight data consumers are possible.

In certain embodiments, one or more engagement agents 324 may be implemented to define various cognitive interactions 340 between a user and a particular cognitive process 330. In certain embodiments, an engagement agent 324 may be implemented to include a mission 328. As used herein, a mission 328 broadly refers to a particular goal the engagement agent 324 is intended to achieve. In certain embodiments, one or more compliance agents 326 may be implemented to ensure compliance with certain business and technical guidelines, rules, regulations or other parameters associated with an organization.

As used herein, a cognitive process 330 broadly refers to an instantiation of one or more cognitive computing operations, described in greater detail herein. In certain embodiments, the cognitive processes 330 may be implemented as an AI campaign orchestration platform 126, one or more cognitive applications 332, or one or more composite applications 334, or a combination thereof. In certain embodiments, a cognitive application 332 may be implemented as an AI campaign 266, described in greater detail herein. As used herein, a composite application 334 broadly refers to a particular combination of two or more cognitive applications, which in certain embodiments, may be implemented to operate in combination with one another.

In certain embodiments, the cognitive processes 330 may be implemented to understand and adapt to the user, not the other way around, by natively accepting and understanding human forms of communication, such as natural language text, audio, images, video, and so forth. In these and other embodiments, the cognitive processes 330 may be implemented to possess situational and temporal awareness based upon ambient signals from users and data, which facilitates understanding the user's intent, content, context and meaning to drive goal-driven dialogs and outcomes. Further, they may be designed to gain knowledge over time from a wide variety of structured, non-structured, transactional, and device data sources, continuously interpreting and autonomously reprogramming themselves to better understand a given domain. As such, they are well-suited to support human decision making, by proactively providing trusted advice, offers and recommendations while respecting user privacy and permissions.

In certain embodiments, the cognitive processes 330 may be implemented in concert with one another. In various embodiments, one or more cognitive processes 330 may be implemented to support plug-ins and components that facilitate the creation of certain AI campaign applications 332, or composite applications 334, or both. In various embodiments, the cognitive processes 330 may be implemented to support certain cognitive interactions 340. In various embodiments, one or more cognitive interactions 340 may be implemented to support user interactions with certain cognitive processes 330 through web 342 applications, mobile 344 applications, chatbot 348 interactions, voice 348 interactions, augmented reality (AR) and virtual reality (VR) 350 interactions, or a combination thereof.

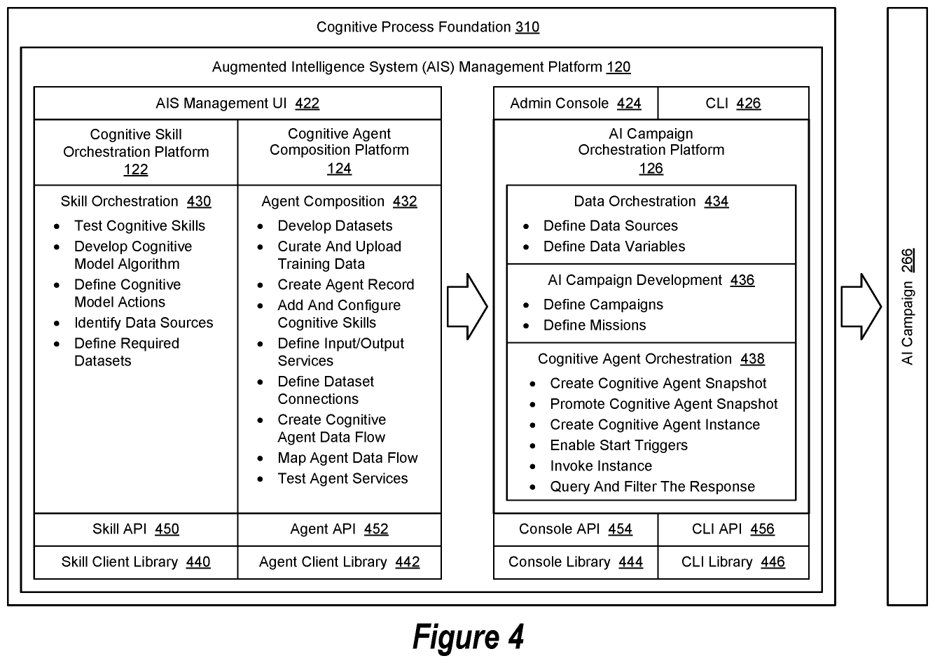

FIG. 4 shows a simplified block diagram of components associated with a cognitive process foundation implemented in accordance with an embodiment of the invention. In certain embodiments, the cognitive process foundation 310 may be implemented to include an augmented intelligence system (AIS) management platform 120, described in greater detail herein. In certain embodiments, the AIS management platform 120 may be implemented to include a cognitive skill orchestration 122 platform, a cognitive agent composition 124 platform, and an AI campaign orchestration 126 platform, or a combination thereof, all of which are described in greater detail herein.

In various embodiments, the AIS management platform 120 may likewise be implemented to include an AIS management user interface (UI) 422. In certain of these embodiments, the AIS management UI 422 may be implemented to receive user input and provide a visual representation of the execution of individual operations, associated with the cognitive skill orchestration 122 and cognitive agent composition 124 platforms. In certain embodiments, the AIS management UI 422 may be implemented as a Graphical User Interface (GUI).

In various embodiments, the cognitive skill orchestration 122 platform may be implemented to perform certain cognitive skill orchestration 430 operations associated with the orchestration of one or more cognitive skills. In certain embodiments, the cognitive skill orchestration 430 operations may include the testing of a cognitive skill, as described in greater detail herein. In certain embodiments, the cognitive skill orchestration 430 operations may include the development of one or more cognitive algorithms, as likewise described in greater detail herein. In certain embodiments, the cognitive skill orchestration 430 operations may include the definition of various cognitive model actions. In certain embodiments, the cognitive skill orchestration 430 operations may include the identification of data sources, such as the public 202, proprietary 204, transaction, social 208, device 210, and ambient 212 data sources described in the descriptive text associated with FIG. 2. In certain embodiments, the cognitive skill orchestration 430 operations may include the definition of required datasets, described in greater detail herein.

In certain embodiments, the cognitive skill orchestration platform 122 may be implemented with an associated cognitive skill client library 440 and one or more cognitive skill Application Program Interfaces (APIs) 450. In certain embodiments, the cognitive skill client library 440, and one or more cognitive skill APIs 450, may be implemented by the cognitive skill orchestration platform 122 to orchestrate a particular cognitive skill.

In various embodiments, the cognitive agent composition platform 124 may be implemented to perform certain cognitive agent composition 432 operations associated with the composition of a particular cognitive agent. In certain embodiments, the cognitive agent composition 432 operations may include the development of various datasets used by a particular cognitive agent during its execution. In various embodiments, the cognitive agent composition 432 operations may include the curation and uploading of certain training data used by a cognitive model associated with a particular cognitive agent. In certain embodiments, the development of the various datasets and the curation and uploading of certain training data may be performed via a data engineering operation.

In certain embodiments, the cognitive agent composition 432 operations may include creation of a cognitive agent record. In certain embodiments, the cognitive agent record may be implemented by an AIS to track a particular cognitive agent. In certain embodiments, the cognitive agent record may be implemented by an AIS to locate and retrieve a particular cognitive agent stored in a repository of AIS components, described in greater detail herein. In certain embodiments, the cognitive agent composition 432 operations may include the addition, and configuration of, one or more cognitive skills associated with a particular cognitive agent.

In certain embodiments, the cognitive agent composition 432 operations may include the definition of various input/output services, described in greater detail herein, associated with a particular cognitive agent. In certain embodiments, the cognitive agent composition 432 operations may include the definition of various dataset connections associated with a particular cognitive agent. In certain embodiments, the definition of various dataset connections may be performed via a data engineering operation.

In certain embodiments, the cognitive agent composition 432 operations may include the creation of one or more data flows associated with a particular cognitive agent. In certain embodiments, the cognitive agent composition 432 operations may include the mapping of one or more data flows associated with a particular cognitive agent. In certain embodiments, the mapping of data flows may be performed via a date engineering operation. In certain embodiments, the cognitive agent composition 432 operations may include the testing of various services associated with a particular cognitive agent.

In certain embodiments, the cognitive agent composition platform 124 may be implemented with an associated cognitive agent client library 442 and one or more cognitive agent APIs 452. In certain embodiments, the cognitive agent library 442, and one or more cognitive agent APIs 452, may be used by the cognitive agent composition platform 124 to compose a particular cognitive agent.

In certain embodiments, the AIS management platform 120 may be implemented to include an AI campaign orchestration platform 126. In various embodiments, the AI campaign orchestration platform 126 may be implemented to perform certain data orchestration 434, AI campaign development 436, and cognitive agent orchestration 438 operations, or a combination thereof. In certain embodiments, the data orchestration 434 operations may include the definition of data sources associated with a particular AI campaign 266. In certain embodiments, the data orchestration 434 operations may include the definition of various data variables associated with a particular AI campaign 266.

In certain embodiments, the AI campaign development 436 operations may include the definition of AI campaigns 266, or missions, or both, as described in greater detail herein. In certain embodiments, the cognitive agent orchestration 438 operations may include the creation of a cognitive agent snapshot. As used herein, a cognitive agent snapshot broadly refers to a depiction of the operational state of a cognitive agent at a particular instance in time during the execution of a cognitive process.

In certain embodiments, the cognitive agent orchestration 438 operations may include the promotion of a cognitive agent snapshot. As likewise used herein, promotion broadly refers to the transition of a cognitive agent, or a cognitive process, from one operational environment to another. As an example, the AI campaign orchestration platform 126 may be implemented in a development environment to generate a cognitive process by orchestrating certain cognitive agents, as described in greater detail herein. Once development has been completed, the resulting cognitive process may be promoted to a test environment. Thereafter, once testing of the cognitive process has been completed, it may be promoted to a user acceptance environment, and once the user acceptance phase has been completed, it may be promoted to a production environment.

In certain embodiments, the cognitive agent orchestration 438 operations may include the creation of a cognitive agent instance. In certain embodiments, the cognitive agent orchestration 438 operations may include enablement of start triggers for a particular cognitive agent. In certain embodiments, the cognitive agent orchestration 438 operations may include the invocation of a particular instance of a cognitive agent. In certain embodiments, the cognitive agent orchestration 438 operations may include querying and filtering responses received from a particular cognitive agent.

In certain embodiments, the AI campaign orchestration platform 126 may be implemented to include an AIS administration console 424, an AIS command line interface (CLI) 426, or both. In certain embodiments, the AIS administration console 424 may be implemented as a GUI. In certain embodiments, the cognitive process orchestration platform 126 may be implemented with an associated AIS console client library 444, one or more AIS console APIs 454, an AIS CLI client library 446, one or more AIS CLI APIs 456, or a combination thereof. In various embodiments, the AIS administration console 424 and the AIS CLI 426, individually or in combination, may be implemented to perform certain data orchestration 434, AI campaign development 436, and cognitive agent orchestration 438 operations, or a combination thereof.

In certain embodiments, the AIS administration console 424 and the AIS CLI 426, individually or in combination, may be implemented to orchestrate the individual components, or processes, associated with a particular AI campaign 266, described in greater detail herein, over its lifecycle. In certain embodiments, the individual components of a particular AI campaign 266 may include one or more cognitive agents, likewise described in greater detail herein. In certain embodiments, the AIS administration console 424 and the AIS CLI 426, individually or in combination, may be implemented to manage the implementation of one or more cognitive agents associated with a particular AI campaign 266.

In certain embodiments, the AIS administration console 424 may be implemented to manage an AI campaign 266 user account. In certain embodiments, the AIS administration console 424 may be implemented view various AIS logs and metrics. In certain embodiments, the AIS administration console 424 may be implemented as a web interface familiar to those of skill in the art.

In certain embodiments, the AIS CLI 426 may be implemented to generate and deploy cognitive skills, created and save dataset definitions, invoke cognitive agent services, and configure cognitive action batch jobs and connections, or a combination thereof. In certain embodiments, the AIS CLI 426 may be implemented to add cognitive agent components to the AI campaign orchestration platform 126. In certain embodiments, the AIS CLI 426 may be implemented to execute cognitive agent lifecycle commands.

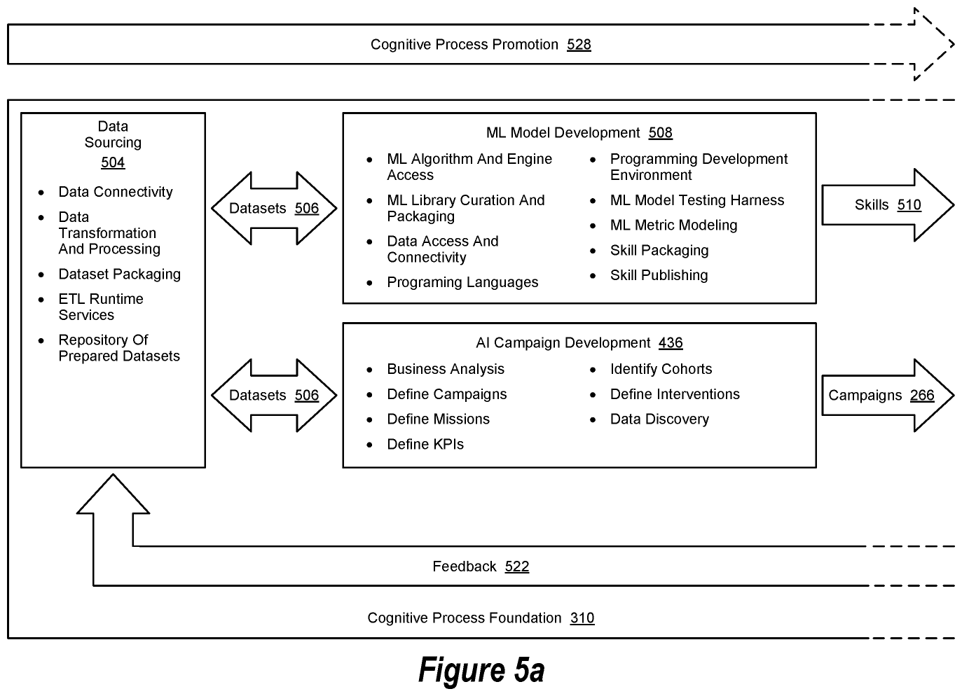

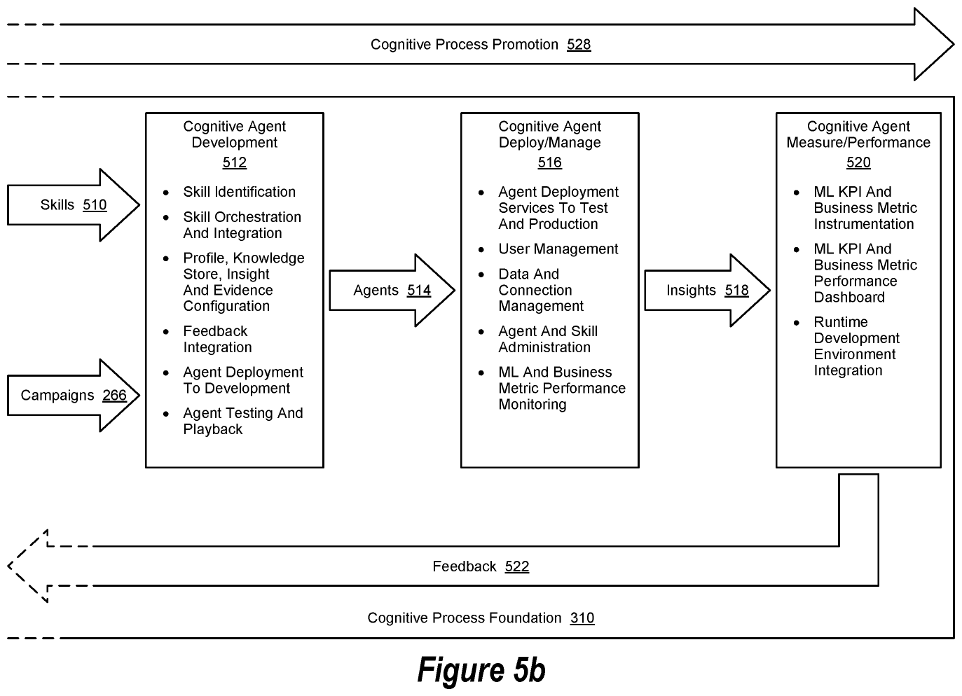

FIGS. 5a and 5b are a simplified process diagram showing the performance of cognitive process promotion operations implemented in accordance with an embodiment of the invention. In various embodiments, a cognitive process foundation 310, described in greater detail herein, may be implemented to perform certain cognitive process promotion 528 operations associated with promoting a particular cognitive process from one operating environment to another.

As shown in FIG. 5a, certain operations may be performed in a data sourcing 504 phase, which results in the generation of various data sets 506, which are then used in a machine learning (ML) model development 508 and augmented intelligence (AI) campaign development 436 phases, described in greater detail herein. In turn, the resulting ML model and AI campaign development results may then respectively be incorporated into one or more cognitive skills 510 and AI campaigns 266, which are then used in a cognitive agent development 512 phase to generate various cognitive agents 514.

The resulting cognitive agents 514, as shown in FIG. 5b, may then be implemented in a cognitive agent deployment and management 516 phase, which results in the generation of one or more insights 518. In turn, the one or more insights 518 may be used in a cognitive agent measurement and performance 520 phase, which results in the generation of feedback 522, which in turn is provided to the data sourcing 504 phase.

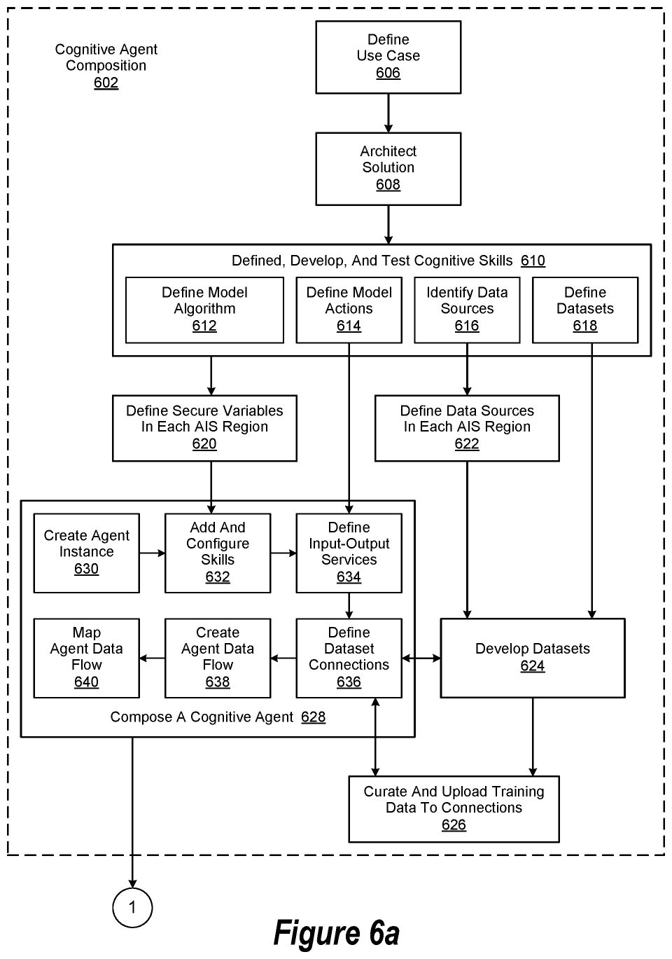

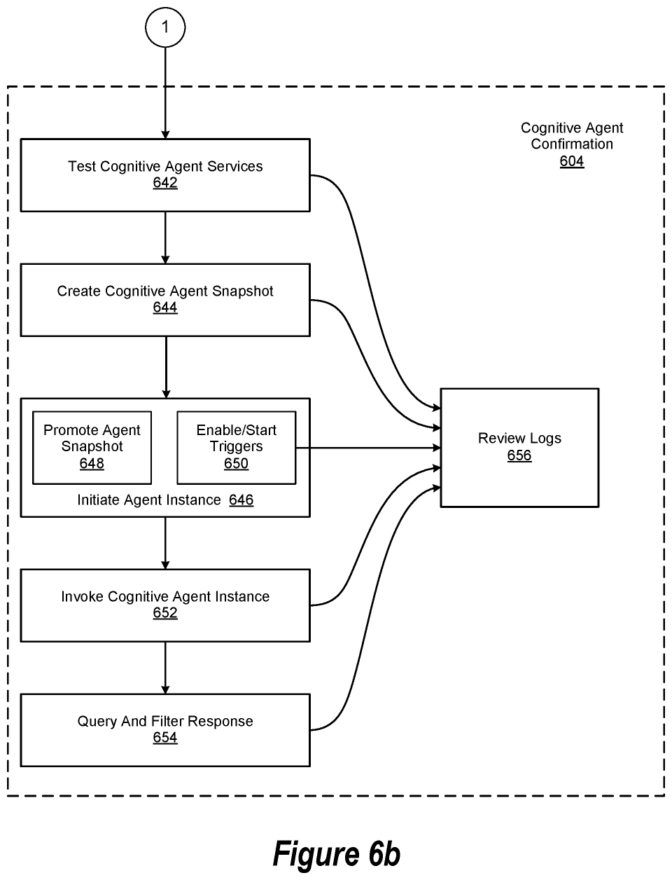

FIGS. 6a and 6b are a simplified process flow showing the lifecycle of augmented intelligence agents implemented in accordance with an embodiment of the invention to perform augmented intelligence system (AIS) operations. In certain embodiments, a cognitive agent lifecycle may include a cognitive agent composition 602 phase and a cognitive agent confirmation 604 phase. In certain embodiments, the cognitive agent composition 602 phase may be initiated with the definition of a cognitive process use case in step 606, followed by architecting an associated solution in step 608.

One or more cognitive skills associated with the architected solution are then defined, developed and tested in step 610. In certain embodiments, a machine learning (ML) model associated with the architected solution is defined in step 612. In certain embodiment, cognitive actions, described in greater detail herein, are defined for the ML model in step 614. In certain embodiments, data sources for the architected solution are identified in step 616 and corresponding datasets are defined in step 618.

The ML model definitions defined in step 612 are then used in step 620 to define variables that need to be secured in the implementation of each associated AIS region, described in greater detail herein. Likewise, the data sources identified in step 616 are used in step 622 to define data sources corresponding to each associated AIS region. Thereafter, the data sources defined in step 622 and the datasets defined in step 618 are used in step 624 to define datasets that will be used to compose a cognitive agent in step 628. Once the datasets have been developed in in step 624, they are used to curate and upload training data to associated data source connections in step 626.

Cognitive agent compositions operations are then initiated in step 628 by creating a cognitive agent instance in step 630. Once created, the secured variables defined in step 620 are added to one or more cognitive skills, which in turn are configured in step 632. The ML model actions defined in step 614 are then used in step 634 to define input and output services for the one or more cognitive skills configured in step 632. Thereafter, the datasets developed in step 624 are used in step 636, along with the training data curated and uploaded in step 626 to define dataset connections. A dataflow is then created for the cognitive agent in step 638 and mapped in step 640.

The cognitive agent confirmation 604 phase is then initiated in step 642 by testing various service associated with the cognitive agent composed in step 628. Thereafter, a cognitive agent snapshot 644, described in greater detail herein, is then created in step 644. In certain embodiments, the cognitive agent snapshot 644 may include versioning and other descriptive information associated with the cognitive agent.

An instance of the cognitive agent is then initiated in step 646. In certain embodiments, initiation of the cognitive agent may include promoting a snapshot of the cognitive agent in step 648 and enabling start and stop triggers in step 650. The instance of the cognitive agent that was initiated in step 646 is then invoked for execution in step 652, followed by performing queries and filtering associated responses in step 654. In certain embodiments, log entries corresponding to the operations performed in step 642 through 654 are reviewed in step 656.

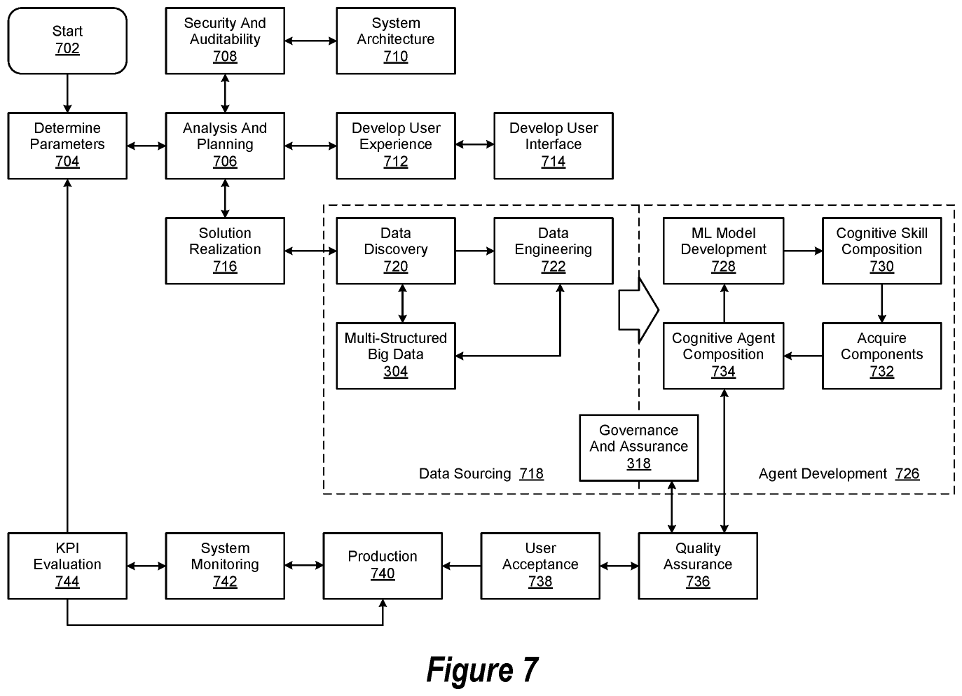

FIG. 7 is a simplified process diagram showing phases of a cognitive process lifecycle implemented in accordance with an embodiment of the invention. As used herein, a cognitive process lifecycle broadly refers to a series of phases, or individual operational steps, or a combination thereof, associated with a cognitive process, spanning its inception, development, implementation, testing, acceptance, production, revision, and eventual retirement. In certain embodiments, each phase or operational step of a cognitive process lifecycle may have associated input artifacts, roles or actors, and output artifacts.

As used herein, an input artifact broadly refers to an article of information used to perform an operation associated with completion of a certain phase, or performance of certain operational steps, of a cognitive process lifecycle. Examples of input artifacts include articles of information related to business and technical ideas, goals, needs, structures, processes, and requests. Other examples of input artifacts include articles of information related to market and technical constraints, system architectures, and use cases. Yet other examples of input artifacts include articles of information related to data sources, previously-developed technology components, and algorithms.

As likewise used herein, a role or actor broadly refers to a particular user, or certain functions they may perform, participating in certain phases or operational steps of a cognitive process lifecycle. Examples of roles or actors include business owners, analysts, and partners, user experience (UX) and user interface (UI) designers, and project managers, as well as solution, enterprise and business process architects, Other examples of roles or actors include data scientists, machine learning (ML) engineers, data, integration and software engineers, as well as system administrators.

An output artifact, as likewise used herein, broadly refers to an article of information resulting from the completion of a certain phase, or performance of certain operational steps, of a cognitive process lifecycle. Examples of output artifacts include Strength/Weaknesses/Opportunity/Threat (SWOT) analysis results, Key Performance Indicator (KPI) definitions, and project plans. Other examples of output artifacts include use case models and documents, cognitive application UX and UI designs, and project plans. Yet other examples of output artifacts include dataset, algorithm, machine learning (ML) model, cognitive skill, and cognitive agent specifications, as well as their corresponding datasets, algorithms, ML models, cognitive skills, and cognitive agents. Those of skill in the art will recognize that many examples of input artifacts, roles or actors, and output artifacts are possible. Accordingly, the foregoing is not intended to limit the spirit, scope or intent of the invention.

In this embodiment, a cognitive process lifecycle is begun in step 702, followed by determining certain operational and performance parameters related to an associated cognitive process in step 704. The resulting operational and performance parameters are then used in step 706 for use in various business analysis and planning purposes, described in greater detail herein. Information security and audibility issues associated with the cognitive process are then identified and addressed in step 708, followed by reviews of the existing system and cognitive architecture, and any resulting updates, being performed in step 710. Likewise, the user experience (UX) and one or more user interfaces (UIs) associated with the cognitive process are respectively developed in steps 712 and 714.

Thereafter, solution realization operations, described in greater detail herein, are performed in step 716 to identify requirements and generate specifications associated with data sourcing 718 and cognitive agent development 726 phases of the cognitive process lifecycle. Once solution realization operations are completed in step 716, data sourcing 718 operations are begun in step 720 with the performance of various data discovery operations, described in greater detail herein. In certain embodiments, the data discovery operations may be performed by accessing various multi-structured, big data 304 sources, likewise described in greater detail herein. Once the data discovery operations have been completed, then certain data engineering operations are performed in step 722 to prepare the sourced data for use in the cognitive agent development 726 phase. As used herein, data engineering refers to processes associated with data collection and analysis as well as validation of the sourced data. In various embodiments, the data engineering operations may be performed on certain of the multi-structured, big data 304 sources.

Once the data sourcing 718 phase has been completed, the cognitive agent development 726 phase is begun in step 728 with development of one or more machine learning (ML) models associated with the cognitive process. Any cognitive skills associated with the cognitive process that may not currently exist are composed in step 730. In certain embodiments, an ML model developed in step 728 may be used to compose a cognitive skill in step 730. Associated cognitive process components are then acquired in step 732 and used in step 734 to compose a cognitive agent. The foregoing steps in the cognitive agent development 726 phase are then iteratively repeated until all needed cognitive agents have been developed.

Once the cognitive agent development 726 phase has been completed, quality assurance and user acceptance operations associated with the cognitive process are respectively performed in step 736 and 738. In various embodiments, certain AI governance and assurance operations 318, described in greater detail herein, may be performed as part of the quality assurance operations 736. The cognitive process is then promoted, as described in greater detail herein, into a production phase in step 740. Once the cognitive process is operating in a production phase, ongoing system monitoring operations are performed in step 742 to collect certain performance data. The performance data resulting from the monitoring operations performed in step 742 is then used in step 744 to perform various Key Performance Indicator (KPI) evaluation operations.

In turn, the results of the KPI evaluations are then used as feedback to improve the performance of the cognitive process. In certain embodiments, the results of the KPI evaluations may be provided as input in step 704 to determine additional operational and performance parameters related to the cognitive process. In certain embodiments, these additional operational and performance parameters may be used to repeat one or more steps associated with the lifecycle of the cognitive process to revise its functionality, improve its performance, or both.

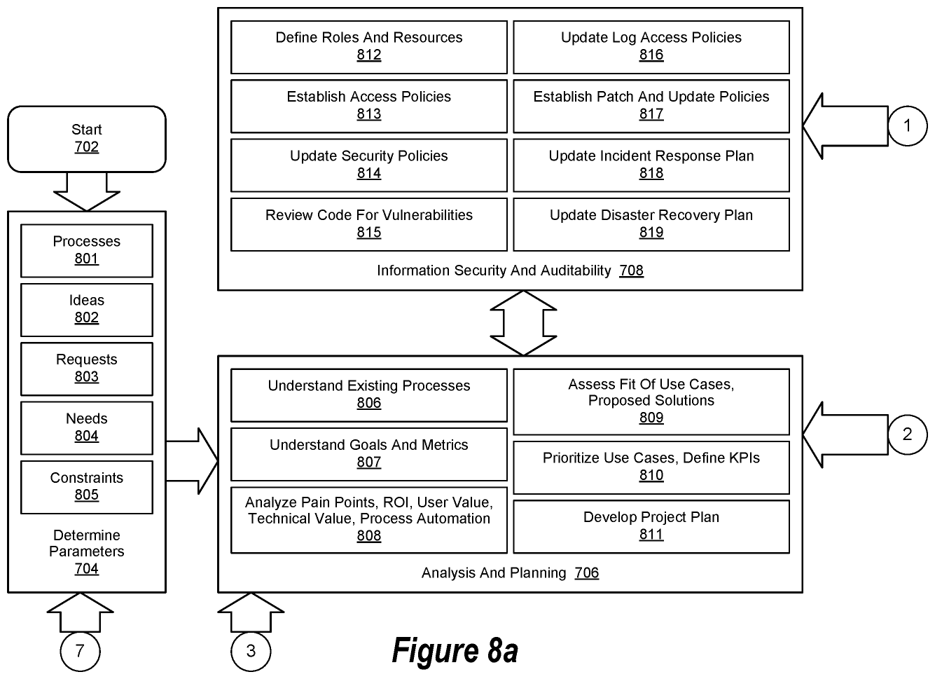

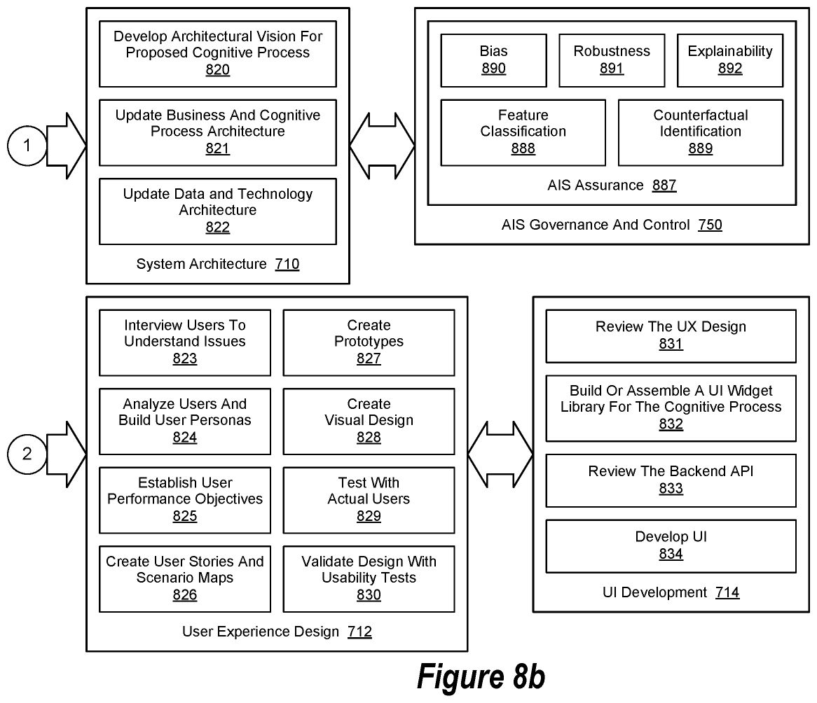

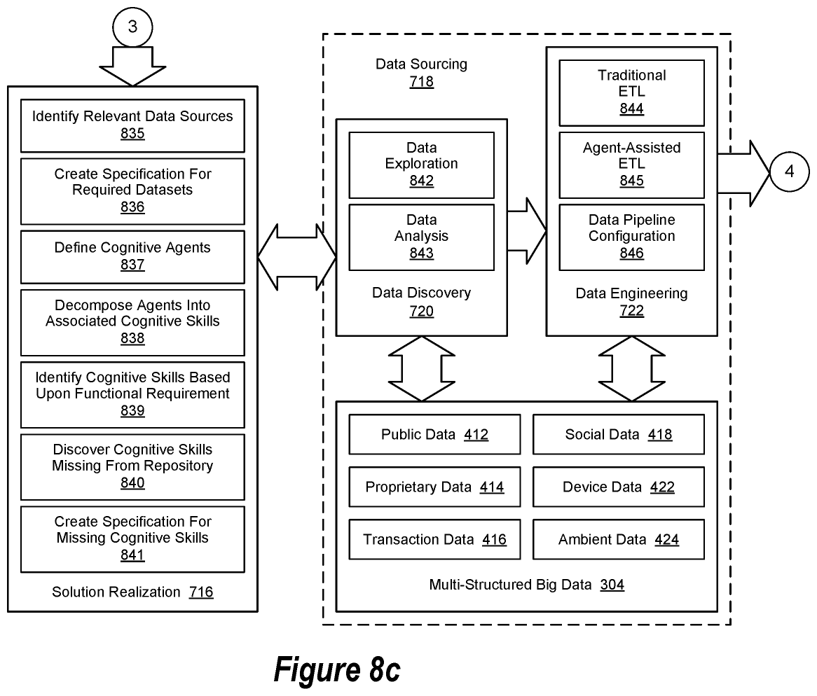

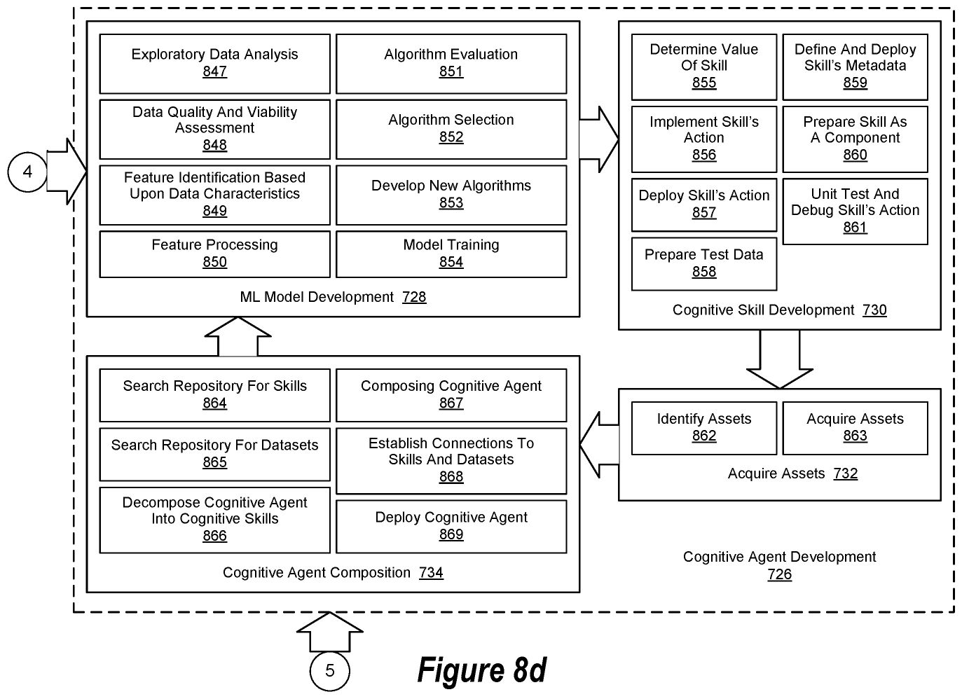

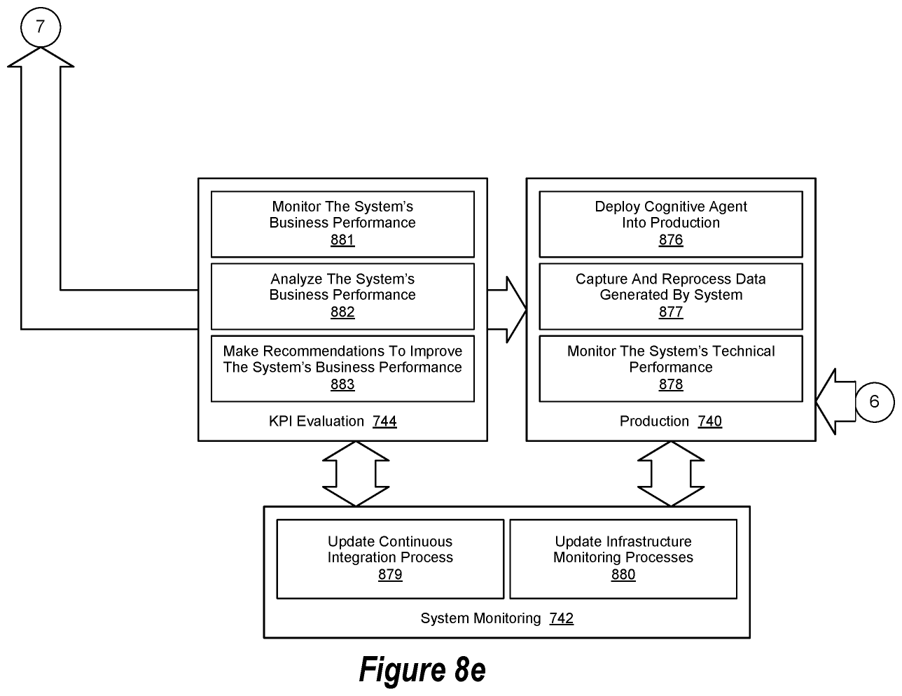

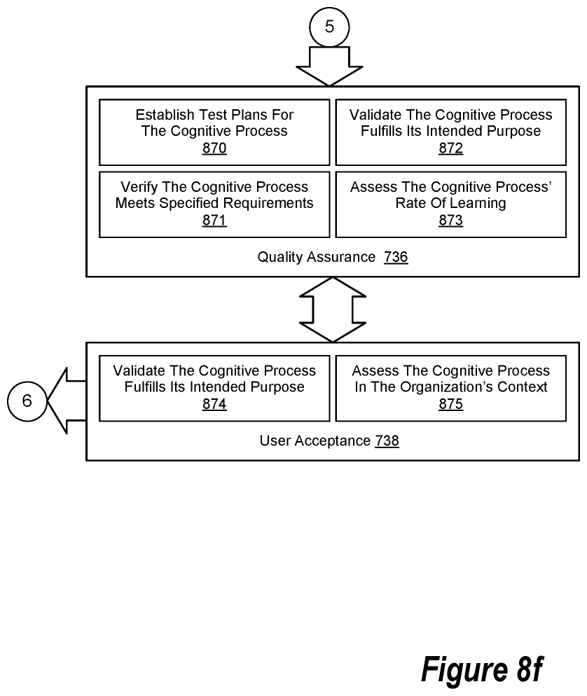

FIGS. 8a through 8f show operations performed in certain phases of a cognitive process lifecycle implemented in accordance with an embodiment of the invention. In this embodiment, a cognitive process lifecycle is begun in step 702, followed by determining certain operational and performance parameters related to an associated cognitive process in step 704. In certain embodiments, the operational and performance parameters determined in step 704 may include parameters related to business and technical processes 801, ideas 802, requests 803, needs 804, and constraints 805, or a combination thereof.

In certain embodiments, the operational and performance parameters resulting from step 704 may then be used for various business analysis and planning purposes in step 706. In certain embodiments, the business and planning purposes may include understanding existing business and technical processes 806. In certain embodiments, the business and planning purposes may include understanding business and technical goals and metrics 807. In certain embodiments, the business and planning purposes may include analyzing business and technical pain points, return on investment (ROI), user value, technical value, and process automation, or a combination thereof 808.

In certain embodiments, the business and planning purposes may include assessing business and technical fit of use cases and proposed solutions 809. In certain embodiments, the business and planning purposes may include prioritizing use cases and defining Key Performance Indicators (KPIs) 810. In certain embodiments, the business and planning purposes may include development of a project plan 811.

In certain embodiments, information security and audibility issues associated with the cognitive process may be identified and addressed in step 708. In certain embodiments, the information security and auditability issues may include defining roles and resources 812, establishing access policies 813, updating security policies 814, and reviewing code for vulnerabilities 815, or a combination thereof. In certain embodiments, the information security and auditability issues may include updating log access policies 816, establishing patch and update policies 817, and updating incidence response 818 and disaster recovery 819 plans, or a combination thereof.

In certain embodiments, reviews of the existing system and cognitive architecture, and any resulting updates, may be performed in step 710. In certain embodiments, reviews of the existing system and cognitive architecture, and any resulting updates, may include developing an architectural vision for a proposed cognitive process 820. In certain embodiments, reviews of the existing system and cognitive architecture, and any resulting updates, may include updating certain business and cognitive process architectures 821. In certain embodiments, reviews of the existing system and cognitive architecture, and any resulting updates, may include updating certain data and technology architectures 822.

In certain embodiments, the user experience (UX) and one or more user interfaces (UIs) associated with the cognitive process may be respectively developed in steps 712 and 714. In certain embodiments, development of the UX design may include interviewing user to understand issues 823 associated with the cognitive process. In certain embodiments, development of the UX design may include analyzing users and building user personas 824 associated with the cognitive process. In certain embodiments, development of the UX design may include establishing user performance objectives 825 associated with the cognitive process.

In certain embodiments, development of the UX design may include creating user stories and scenario maps 826 associated with the cognitive process. In certain embodiments, development of the UX design may include the creation of one or more visual designs 827 associated with the cognitive process. In certain embodiments, development of the UX design may include testing UX designs associated with the cognitive process with actual users 829. In certain embodiments, development of the UX design may include validating design of the UX associated with the cognitive process with usability tests 830.

In certain embodiments, development of the UI may include reviewing the UX design 831 associated with the cognitive process. In certain embodiments, development of the UI may include building or assembling a UI widget library 832 associated with the cognitive process. In certain embodiments, development of the UI may include reviewing the backend Application Program Interface (API) associated with the cognitive process. In certain embodiments, development of the UI may include developing one or more UIs associated with the cognitive process.

In certain embodiments, solution realization operations may be performed in step 716 to identify requirements and generate specifications associated with data sourcing 718 and cognitive agent development 726 phases of the cognitive process lifecycle. In certain embodiments, the solution realization operations may include identification of data sources 835 relevant to the cognitive process. In certain embodiments, the solution realization operations may include the creation of specifications for datasets 836 required by the cognitive process. In certain embodiments, the solution realization operations may include the definition of various cognitive agents 837 associated with the cognitive process.

In certain embodiments, the solution realization operations may include the decomposition of one or more cognitive agents into corresponding cognitive skills 838 associated with the cognitive process. In certain embodiments, the solution realization operations may include identifying various cognitive skills based upon functional requirements 839 associated with the cognitive process. In certain embodiments, the solution realization operations may include discovery of missing cognitive skills 840 associated with the cognitive process. In certain embodiments, the solution realization operations may include creating specifications for missing cognitive skills 841 associated with the cognitive process.

In certain embodiments, the data sourcing 718 phase may be initiated in step 720 with the performance of various data discovery operations. In certain embodiments, the data discovery operations may include various data exploration 842 and data analysis 843 operations, described in greater detail herein. In certain embodiments, the data discovery operations may be performed by accessing various multi-structured, big data 304 sources. In certain embodiments, as described in greater detail herein, the multi-structured big data 304 sources may include public data 412, proprietary data 414, transaction data 416, social data 418, device data 422, ambient data 424, or a combination thereof.

In various embodiments, once the data discovery operations have been completed, certain data engineering operations may be performed in step 722 to prepare the sourced data for use in the cognitive agent development 726 phase. In various embodiments, the data engineering operations may be performed on certain of the multi-structured, big data 304 sources. In certain embodiments, the data engineering operations may include traditional 844 extract, transform, load (ETL) operations. In certain embodiments, the data engineering may include cognitive agent-assisted ETL 845 operations. In certain embodiments, the data engineering operations may include data pipeline configuration 146 operations to skilled practitioners of the art.

In certain embodiments, once the data sourcing 718 phase has been completed, the cognitive agent development 726 phase may be initiated in step 728 with development of one or more machine learning (ML) models associated with the cognitive process. In various embodiments, operations associated with the ML model development may include exploratory data analysis 847, data quality and viability assessment 848, and feature identification based upon certain data characteristics, or a combination thereof. In certain embodiments, operations associated with the ML model development may include feature processing 850, algorithm evaluation 851 and assessment 852, development of new algorithms 853, and model training 854, or a combination thereof.

In certain embodiments, any cognitive skills associated with the cognitive process that may not currently exist may then be developed in step 730. In certain embodiments, an ML model developed in step 728 may be used to develop a cognitive skill in step 730. In certain embodiments, operations associated with the development of a cognitive skill may include determining the value of a particular cognitive skill 855, implementing one or more actions 856 associated with a cognitive skill, and deploying a cognitive skill's action 857, or a combination thereof. In various embodiments, operations associated with the development of a cognitive skill may include the preparation of certain test data 858.

In certain embodiments, operations associated with the development of a cognitive skill may include defining and deploying a particular cognitive skill's metadata 859. In certain embodiments, operations associated with the development of a cognitive skill may include preparing a particular cognitive skill as a cognitive process component 860, described in greater detail herein. In certain embodiments, operations associated with the development of a cognitive skill may include unit testing and debugging 861 one or more actions associated with a particular cognitive skill. In certain embodiments, operations associated with acquiring cognitive process components may then be performed in step 732. In certain embodiments, the operations may include identifying 862 and acquiring 863 one or more cognitive process components.

In certain embodiments, operations associated with composing a cognitive agent may then be performed in step 734. In certain embodiments, cognitive process components acquired in step 732 may be used to compose the cognitive agent. In certain embodiments, the operations associated with composing a cognitive agent may include searching a repository of cognitive process components for cognitive skills 864 or datasets 865 associated with the cognitive process.

In certain embodiments, the operations associated with composing a cognitive agent may include decomposing a cognitive agent into associated cognitive skills 866. In certain embodiments, the operations associated with composing a cognitive agent may include composing a cognitive agent 867, establishing connections to associated cognitive skills and data sets 868, and deploying the cognitive agent 869, or a combination thereof. In certain embodiments, the foregoing steps in the cognitive agent development 726 phase may then be iteratively repeated until all needed cognitive agents have been developed.

In certain embodiments, once the cognitive agent development 726 phase has been completed, quality assurance and user acceptance operations associated with the cognitive process are respectively performed in step 736 and 738. In certain embodiments, the quality assurance operations may include establishing test plans 870 for the cognitive process. In certain embodiments, the quality assurance operations may include verifying the cognitive process meets specified requirements 871 associated with the cognitive process.

In certain embodiments, the quality assurance operations may include validating the cognitive process fulfill its intended purpose 872. In certain embodiments, the quality assurance operations may include assessing the cognitive process' rate of learning 873. In certain embodiments, the use acceptance operations may include validating the cognitive process fulfills its intended purpose 874. In certain embodiments, the user acceptance operations may include assessing the cognitive process in the context of the user's organization 873.

In certain embodiments, the cognitive process is then promoted in step 740, as described in greater detail herein, into a production phase. In certain embodiments, operations associated with the production phase may include deploying one or more cognitive agents into production 876. In certain embodiments, operations associated with the production phase may include capturing and reprocessing data generated by the system 877. In certain embodiments, operations associated with the production phase may include monitoring the system's technical performance 878.

In certain embodiments, once the cognitive process is operating in the production phase, ongoing system monitoring operations are performed in step 742 to collect certain performance data. In certain embodiments, the system monitoring operations may include updating a continuous integration process 879. In certain embodiments, the system monitoring operations may include updating infrastructure monitoring processes 880.

In certain embodiments, the performance data resulting from the monitoring operations performed in step 742 may them be used in step 744 to perform various Key Performance Indicator (KPI) evaluation operations. In certain embodiments, the KPI evaluation operations may include monitoring 881 and analyzing 882 the system's business performance. In certain embodiments, the KPI evaluation operations may include making recommendations to improve 883 the systems business performance.

In certain embodiments, the results of the KPI evaluations may be used as feedback to improve the performance of the cognitive process in the production 740 phase. In certain embodiments, the results of the KPI evaluations may be provided as input in step 704 to determine additional operational and performance parameters related to the cognitive process. In certain embodiments, these additional operational and performance parameters may be used to repeat one or more steps associated with the lifecycle of the cognitive process to revise its functionality, improve its performance, or both.

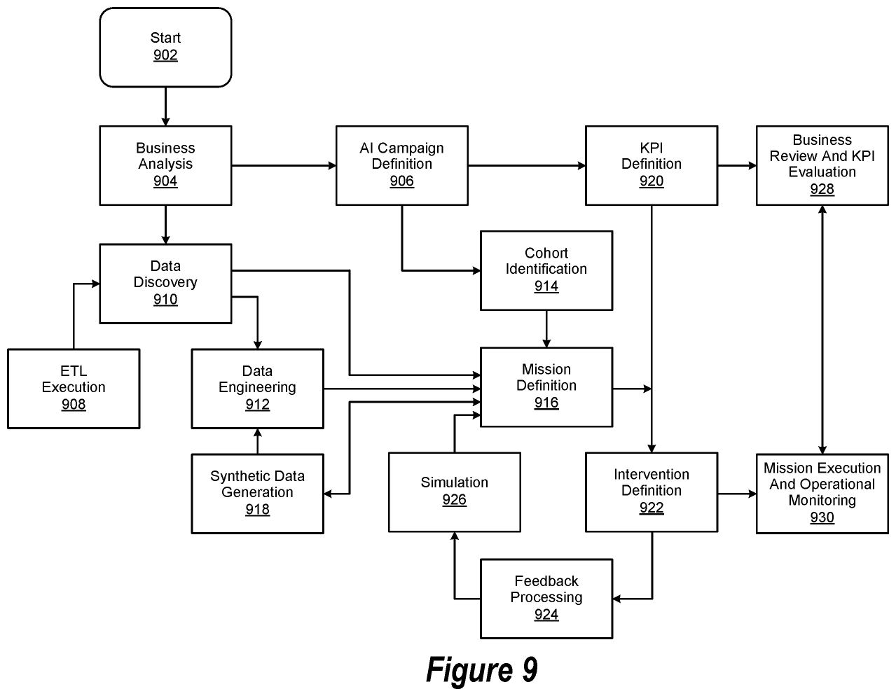

FIG. 9 is a simplified process diagram showing phases of an augmented intelligence (AI) campaign lifecycle implemented in accordance with an embodiment of the invention. In various embodiments, an AI campaign lifecycle may be begun in step 902, followed by the performance of certain business analysis operations, described in greater detail herein, during a business analysis 904 phase. In various embodiments, certain outputs of the business analysis 904 phase may be provided as input data to an AI campaign definition 906 phase and a data discovery 910 phase of the AI campaign lifecycle.

In various embodiments, the AI campaign definition 906 phase of the AI campaign lifecycle may include the performance of certain AI campaign definition operations, likewise described in greater detail herein. In various embodiments, certain outputs of the AI campaign definition 906 phase may be provided as input data to a cohort identification 914 phase and a KPI definition 920 phase of the AI campaign lifecycle. In various embodiments, as described in greater detail herein, an ETL execution 908 phase of the AI campaign lifecycle may include the performance of certain ETL operations. In various embodiments, certain outputs of the ETL execution 908 phase may be provided as input data to a data discovery 910 phase of the AI campaign lifecycle.

In various embodiments, as likewise described in greater detail herein, the data discovery 910 phase of the AI campaign lifecycle may include the performance of certain data discovery operations. In various embodiments, certain outputs of the data discovery 910 phase may be provided as input data to a data engineering 912 phase and a mission definition 916 phase of the AI campaign lifecycle. In various embodiments, the data engineering 912 phase of the AI campaign lifecycle may include the performance of certain data engineering operations, described in greater detail herein. In various embodiments, certain outputs of the data engineering 912 phase may be provided as input data to a mission definition 916 phase of the AI campaign lifecycle.

In various embodiments, the cohort identification 914 phase of the AI campaign lifecycle may include the performance of certain cohort identification operations, likewise described in greater detail herein. As used herein, a cohort broadly refers to a subset of a larger population that shares a particular set of attributes. As an example, recipients of Medicare health services in the United States would be a cohort of the entire population of the United States. As another example, male recipients of Medicare, who are older than sixty five and also happen to reside in the state of Florida would a different cohort.

In various embodiments, certain outputs of the cohort identification 914 phase may be provided as input data to a mission definition 916 phase of the AI campaign lifecycle. In various embodiments, as described in greater detail herein, the mission definition 916 phase of the AI campaign lifecycle may include the performance of certain mission definition operations. In various embodiments, certain outputs of the mission definition 916 phase may be provided as input data to a synthetic data generation 918 phase and the intervention definition 922 phase of the AI campaign lifecycle.

In various embodiments, as likewise described in greater detail herein, the synthetic data generation 918 phase of the AI campaign lifecycle may include the performance of certain synthetic data generation operations. In various embodiments, certain outputs of the synthetic data generation 918 phase may be provided as input data to the data engineering 912 phase, or as feedback data to the mission definition 916 phase, of the AI campaign lifecycle, or both. In various embodiments, the intervention definition 922 phase of the AI campaign lifecycle may include the performance of certain intervention definition operations, described in greater detail herein. In various embodiments, certain outputs of the intervention definition 922 phase may be provided as input data to a feedback processing 924 phase, or a mission execution and operational monitoring 930 phase, of the AI campaign lifecycle, or both.

In various embodiments, the feedback processing 924 phase of the AI campaign lifecycle may include the performance of certain feedback processing operations, likewise described in greater detail herein. In various embodiments, certain outputs of the feedback processing 924 phase may be provided as input data to a simulation 926 phase of the AI campaign lifecycle. In various embodiments, as described in greater detail herein, the simulation 926 phase of the AI campaign lifecycle may include the performance of certain simulation operations. In various embodiments, certain outputs of the simulation 926 phase may be provided as input data to the mission definition 916 phase of the AI campaign lifecycle.

In various embodiments, as likewise described in greater detail herein, the KPI definition 920 phase of the AI campaign lifecycle may include the performance of certain KPI definition operations. In various embodiments, certain outputs of the KPI definition 920 phase may be provided as input data to a business review and KPI evaluation 928 phase of the AI campaign lifecycle. In various embodiments, the business review and KPI evaluation 928 phase of the AI campaign lifecycle may include the performance of certain business review and KPI evaluation operations, described in greater detail herein. In various embodiments, certain outputs of the business review and KPI evaluation 928 phase may be provided as input data to a the mission execution and operational monitoring 930 phase of the AI campaign lifecycle.

In various embodiments, the mission execution and operational monitoring 930 phase of the AI campaign lifecycle may include the performance of certain mission execution and operational monitoring operations. In various embodiments, certain outputs of the mission execution and operational monitoring 930 phase may be provided as feedback data to the business review and KPI evaluation 928 phase of the AI campaign lifecycle. Skilled practitioners of the art will recognize that many embodiments of the invention are possible. Accordingly, the foregoing is not intended to limit the spirit, scope, or intent of the invention.

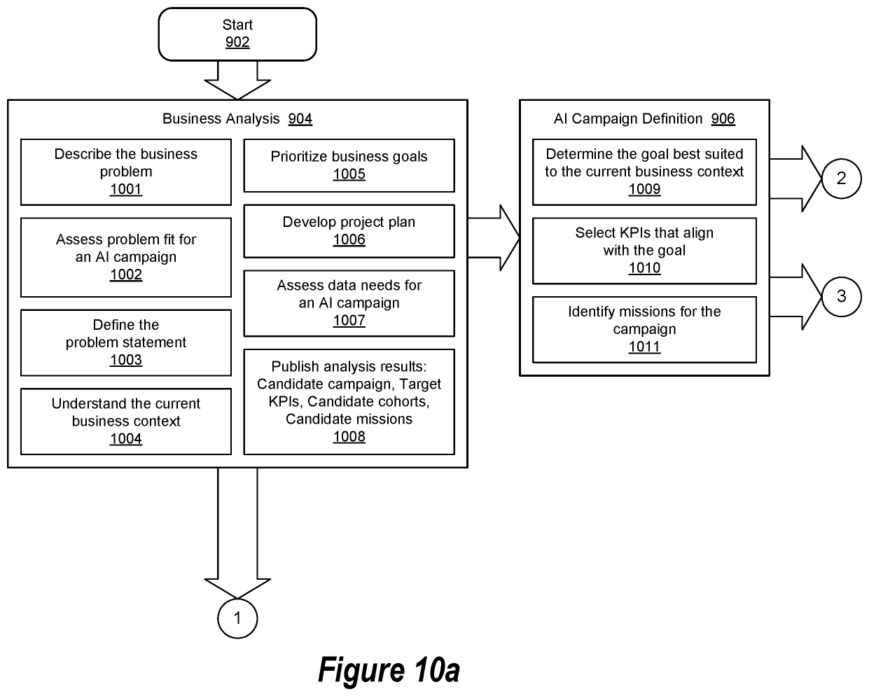

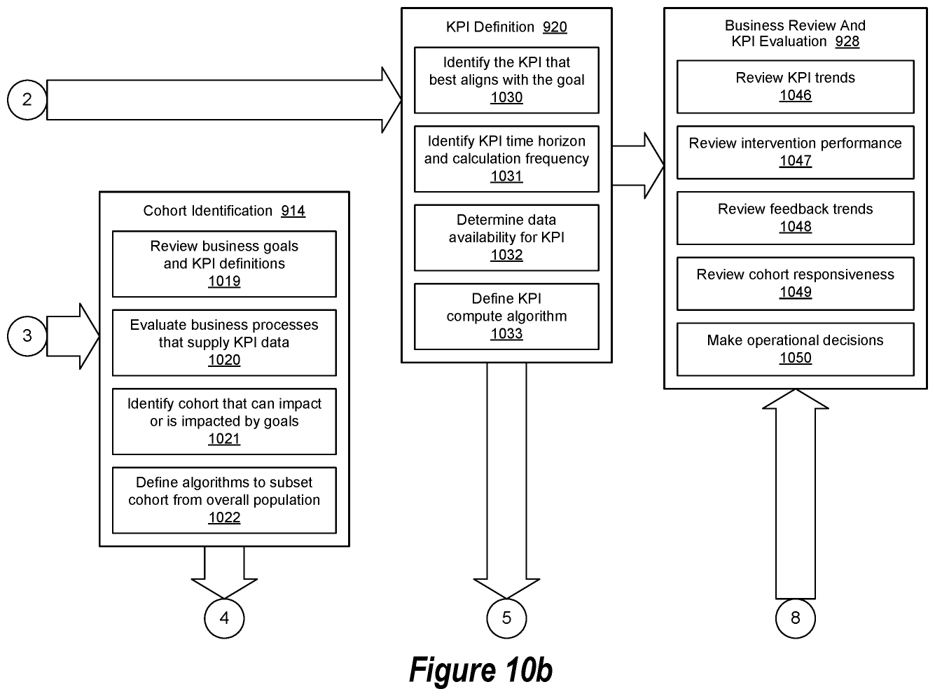

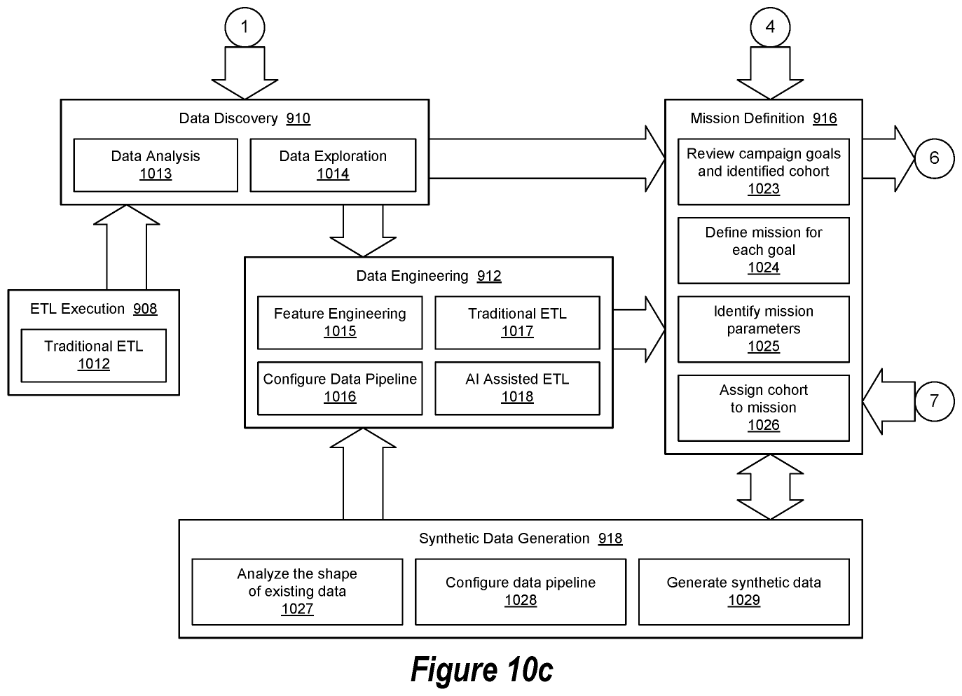

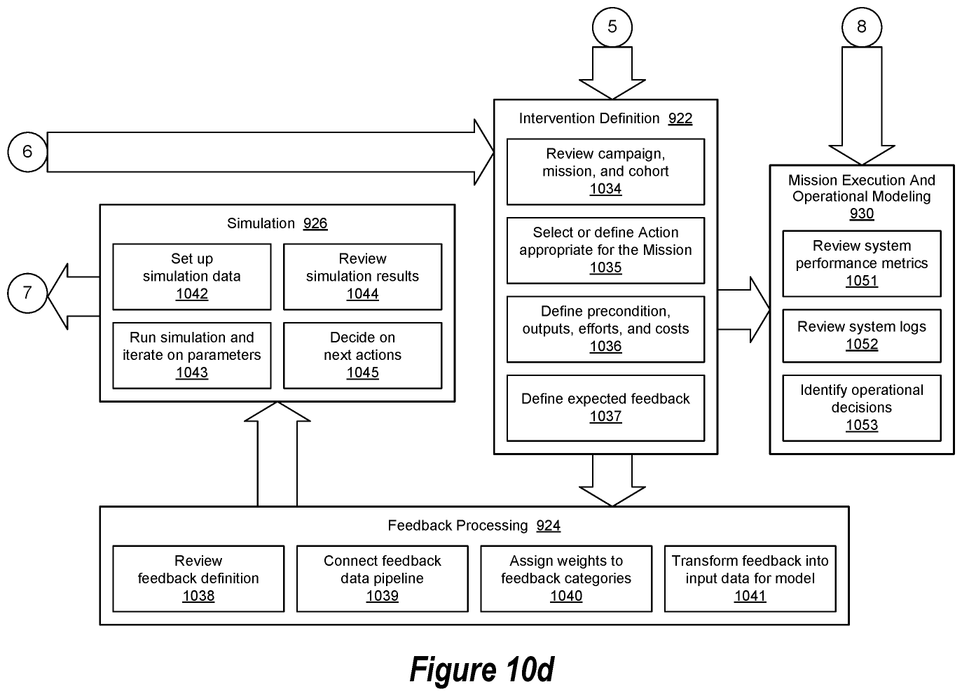

FIGS. 10a through 10d show operations performed in certain phases of an augmented intelligence (AI) campaign lifecycle implemented in accordance with an embodiment of the invention. In various embodiments, an AI campaign lifecycle may be begun in step 902, followed by the performance of certain business analysis operations during a business analysis 904 phase. In various embodiments, certain input data may be used to perform the business analysis operations during the business analysis 904 phase. In certain of these embodiments, the input data may be associated with one or more articulated business needs, one or more business metrics, one or more business ideas, one or more business processes, and one or more market constraints, or a combination thereof.

In various embodiments, the business analysis operations performed during the business analysis 904 phase may include describing a particular business problem 1001, assessing the problem fit for a particular AI campaign 1002, defining the problem statement 1003, and understanding the current business content 1004. In various embodiments, the business analysis operations performed during the business analysis 904 phase may likewise include prioritizing certain business goals 1005, developing a project plan 1006, assessing the data needs for the AI campaign 1007, and publishing the results 1008 of the operations performed during the business analysis 904 phase. In various embodiments, certain of the business analysis operations performed during the business analysis 904 phase may be performed, directly or indirectly, by a business owner, a business analyst, a subject matter expert (SME), a data, or a project engineer, or a combination thereof.

In various embodiments, performance of the business analysis operations during the business analysis 904 phase may result in one or more outputs. In various embodiments, these outputs may include a description of the candidate AI campaign, certain prioritized business goals, certain data requirements, target key performance indicators (KPIs), candidate cohorts and missions, both of which are described in greater detail herein, and a project plan, or a combination thereof. In various embodiments, certain outputs of the business analysis 904 phase may be provided as input data to an AI campaign definition 906 phase and a data discovery 910 phase of the AI campaign lifecycle.

In various embodiments, the AI campaign definition 906 phase of the AI campaign lifecycle may include the performance of certain AI campaign definition operations. In various embodiments, the AI campaign definition operations may include determining the goal best suited to the current business context 1009, selection of KPIs that align with that goal 1010, and identification of certain missions for the AI campaign 1011, or a combination thereof. In various embodiments, the input data used to perform AI campaign definition operations in the AI campaign definition 906 phase of the AI campaign lifecycle may likewise include certain business architecture data.

In various embodiments, certain of the AI campaign definition operations performed during the AI campaign definition 906 phase may be performed, directly or indirectly, by a business owner, a business analyst, or a subject matter expert (SME), or a combination thereof. In various embodiments, performance of the AI campaign definition operations during the campaign definition 906 phase may result in one or more outputs. In various embodiments, these outputs may include, an AI campaign definition, and a candidate cohort, or both. In various embodiments, certain outputs of the AI campaign definition 906 phase may be provided as input data to a cohort identification 914 phase and a KPI definition 920 phase of the AI campaign lifecycle.

In various embodiments, an ETL execution 908 phase of the AI campaign lifecycle may include the performance of certain ETL operations. In various embodiments, the ETL operations may include certain traditional ETL 1012 operations familiar to skilled practitioners of the art. In various embodiments, the input data used to perform the execution of ETL operations in the ETL execution 908 phase of the AI campaign lifecycle may likewise include one or more data sets. In these embodiments, the one or more datasets selected for use in the performance of a particular ETL execution operation, and the method by which it may be used in the performance of such an operation, is a matter of design choice.

In various embodiments, certain of the ETL execution operations performed during the ETL execution 910 phase may be performed, directly or indirectly, by a data engineer, a data scientist, or a machine learning (ML) engineer, or a combination thereof. In various embodiments, performance of the ETL execution operations during the ETL execution 910 phase may result in one or more outputs. In various embodiments, these outputs may include one or more datasets. In these embodiments, the one or more datasets generated as a result of the performance of a particular ETL execution operation, and the method by which they may be generated, is a matter of design choice. In various embodiments, certain outputs of the ETL execution 908 phase may be provided as input data to a data discovery 910 phase of the AI campaign lifecycle.

In various embodiments, the data discovery 910 phase of the AI campaign lifecycle may include the performance of certain data discovery operations. In various embodiments, the data discovery operations may include certain data analysis 1013 operations, or data exploration 1014 operations, or both. In various embodiments, the input data used to perform data discovery operations in the data discovery 910 phase of the AI campaign lifecycle may include one or more datasets. In these embodiments, the one or more datasets selected for use in the performance of a particular data discovery operation, and the method by which it may be used in the performance of such an operation, is a matter of design choice.

In various embodiments, certain of the data discovery operations performed during the AI data discovery 910 phase may be performed, directly or indirectly, by a data engineer, a data scientist, or an ML engineer, or a combination thereof. In various embodiments, performance of the data discovery operations during the data discovery 910 phase may result in one or more outputs. In various embodiments, these outputs may include one or more datasets. In these embodiments, the one or more datasets generated as a result of the performance of a particular data discovery operation, and the method by which they may be generated, is a matter of design choice. In various embodiments, certain outputs of the data discovery 910 phase may be provided as input data to a data engineering 912 phase and a mission definition 916 phase of the AI campaign lifecycle.

In various embodiments, the data engineering 912 phase of the AI campaign lifecycle may include the performance of certain data engineering operations. In various embodiments, the data discovery operations may include certain feature engineering 1015 operations, data pipeline configuration 1016 operations, traditional ETL 1017 operations, and AI assisted ETL 1018 operations, or a combination thereof. In various embodiments, the input data used to perform data engineering operations in the data engineering 912 phase of the AI campaign lifecycle may include certain user feedback data, AI persona data, KPI data, monitoring data of all kinds, one or more datasets, certain graph data, certain Internet of Things (IoT) data, and system alert data, or a combination thereof. In these embodiments, the data selected for use in the performance of a particular data engineering operation, and the method by which it may be used in the performance of such an operation, is a matter of design choice.

In various embodiments, certain of the data engineering operations performed during the AI data engineering 912 phase may be performed, directly or indirectly, by a data engineer, a data scientist, an ML engineer, or a Development Operations (DevOps) engineer, or a combination thereof. In various embodiments, performance of the data engineering operations during the data engineering 912 phase may result in one or more outputs. In various embodiments, these outputs may include one or more datasets. In these embodiments, the one or more datasets generated as a result of the performance of a particular data discovery operation, and the method by which they may be generated, is a matter of design choice. In various embodiments, certain outputs of the data engineering 912 phase may be provided as input data to a mission definition 916 phase of the AI campaign lifecycle.

In various embodiments, the cohort identification 914 phase of the AI campaign lifecycle may include the performance of certain cohort identification operations. In various embodiments, the cohort identification operations may include certain operations associated with the review of business goals and KPI definitions 1019, the evaluation of business processes that supply KPI data 1020, the identification of a cohort that impact, or be impacted by, the goals of the AI campaign 1021, and the definition of algorithms for identifying a cohort subset from an overall population 1022, or a combination thereof. In various embodiments, the input data used to perform cohort identification operations in the cohort identification 914 phase of the AI campaign lifecycle may include data associated with one or more business goals, data associated with an AI campaign definition, one or more KPI definitions, and one or more business processes, or a combination thereof. In these embodiments, the data selected for use in the performance of a particular cohort identification operation, and the method by which it may be used in the performance of such an operation, is a matter of design choice.

In various embodiments, certain of the cohort identification operations performed during the cohort identification 914 phase may be performed, directly or indirectly, by a business owner, a business analyst, or an SME, or a combination thereof. In various embodiments, performance of the cohort identification operations during the cohort identification 914 phase may result in one or more outputs. In various embodiments, these outputs may include one or more target cohorts. In these embodiments, the one or more cohorts identified as a result of the performance of a particular cohort identification operation, and the method by which it may be identified, is a matter of design choice. In various embodiments, certain outputs of the cohort identification 914 phase may be provided as input data to a mission definition 916 phase of the AI campaign lifecycle.

In various embodiments, the mission definition 916 phase of the AI campaign lifecycle may include the performance of certain mission definition operations. In various embodiments, the mission definition operations may include certain operations associated with the review of AI campaign goals and identified cohort 1023, definition of the mission for each goal 1024, the identification of a cohort that impact, or be impacted by, the goals of the AI campaign 1021, identification of parameters for each defined mission 1025, and assignment of the identified cohort to each defined mission, or a combination thereof. In various embodiments, the input data used to perform cohort identification operations in the mission definition 916 phase of the AI campaign lifecycle may include data associated with one or more business goals, data associated with an AI campaign definition, one or more KPI definitions, and one or more cohorts, or a combination thereof. In these embodiments, the data selected for use in the performance of a particular mission definition operation, and the method by which it may be used in the performance of such an operation, is a matter of design choice.

In various embodiments, certain of the mission definition operations performed during the mission definition 916 phase may be performed, directly or indirectly, by a business analyst, an SME, or a software code developer, or a combination thereof. In various embodiments, performance of the mission definition operations during the mission definition 916 phase may result in one or more outputs. In various embodiments, these outputs may include one or more mission definitions, one or more identified cohorts, or an intervention, described in greater detail herein, or a combination thereof. In these embodiments, the outputs resulting from the performance of a particular mission definition operation, and the method by which it may be produced, is a matter of design choice. In various embodiments, certain outputs of the mission definition 916 phase may be provided as input data to a synthetic data generation 918 phase and the intervention definition 922 phase of the AI campaign lifecycle.

In various embodiments, the synthetic data generation 918 phase of the AI campaign lifecycle may include the performance of certain synthetic data generation operations. In various embodiments, the synthetic data generation operations may include certain operations associated with analyzing the shape of existing data 1027, configuring a data pipeline 1028, or generating synthetic data 1029, or a combination thereof. As used herein, shape, as it relates to data, broadly refers to a summarization of information contained in a dataset to quickly describe which values are more common and those that are not. As likewise used herein, synthetic data broadly refers to information that is artificially manufactured rather than generated by real-world events. In certain embodiments, the synthetic data may be created algorithmically. In certain embodiments, the synthetic data may be used as a stand-in for test datasets of production or operational data. In certain embodiments, the synthetic data may be used to validate mathematical models, or train machine learning models, or both.

In various embodiments, the input data used to perform synthetic data generation operations in the synthetic data generation 918 phase of the AI campaign lifecycle may include data associated with a particular system of records, user feedback data, user profile data, monitoring data, KPI data, graph data, IoT data, and system alert data, or a combination thereof. As used herein, a system of records, also commonly referred to as a source system of records, broadly refers an authoritative source of data for a particular data element or piece of information. In certain embodiments, the data selected for use in the performance of a particular synthetic generation operation, and the method by which it may be used in the performance of such an operation, is a matter of design choice.

In various embodiments, certain of the synthetic data generation operations performed during the synthetic data generation 918 phase may be performed, directly or indirectly, by a data engineer, a data scientist, an ML engineer, or a DevOps engineer, or a combination thereof. In various embodiments, performance of the synthetic data generation operations during the synthetic data generation 918 phase may result in one or more outputs. In various embodiments, these outputs may include one or more operational dataset, one or more external datasets, of a combination of the two. In these embodiments, the one or more datasets generated as a result of the performance of a particular synthetic data generation operation, and the method by which it may be generated, is a matter of design choice. In various embodiments, certain outputs of the synthetic data generation 918 phase may be provided as input data to the data engineering 912 phase, or as feedback data to the mission definition 916 phase, of the AI campaign lifecycle, or both.

In various embodiments, the intervention definition 922 phase of the AI campaign lifecycle may include the performance of certain intervention definition operations. In various embodiments, the intervention definition operations may include certain operations associated with the review of a particular AI campaign, mission, and cohort 1034, the selection or definition of an action appropriate for a particular mission 1035, definition of one or more preconditions, outputs, efforts, or costs 1036, and definition of one or more expected feedbacks, or a combination thereof. In various embodiments, the input data used to perform cohort identification operations in the mission definition 916 phase of the AI campaign lifecycle may include data associated with definition of a particular AI campaign, the definition of a particular mission, one or more cohorts, or a particular technology infrastructure, or a combination thereof. In these embodiments, the data selected for use in the performance of a particular intervention definition operation, and the method by which it may be used in the performance of such an operation, is a matter of design choice.

In various embodiments, certain of the intervention definition operations performed during the intervention definition 922 phase may be performed, directly or indirectly, by an SME, or a software code developer, or a combination of the two. In various embodiments, performance of the intervention definition operations during the intervention definition 922 phase may result in one or more outputs. In various embodiments, these outputs may include one or more deployable interventions, described in greater detail herein, and one or more feedback specifications, or a combination thereof. In these embodiments, the outputs resulting from the performance of a particular intervention definition operation, and the method by which it may be produced, is a matter of design choice. In various embodiments, certain outputs of the intervention definition 922 phase may be provided as input data to a feedback processing 924 phase, or a mission execution and operational monitoring 930 phase, of the AI campaign lifecycle, or both.

In various embodiments, the feedback processing 924 phase of the AI campaign lifecycle may include the performance of certain feedback processing operations. In various embodiments, the feedback processing operations may include certain operations associated with the review of one or more feedback definitions 1038, connecting to one or more feedback data pipelines 1039, assigning weights to certain feedback categories 1040, and transforming feedback data into input data for a particular model 1041, or a combination thereof. In various embodiments, the input data used to perform feedback processing operations in the feedback processing 924 phase of the AI campaign lifecycle may include data associated with one or more feedback definitions, data associated with one or more intervention logs, data associated with one or more feedback logs, or a combination thereof. In these embodiments, the data selected for use in the performance of a particular feedback processing operation, and the method by which it may be used in the performance of such an operation, is a matter of design choice.

In various embodiments, certain of the feedback processing operations performed during the feedback processing 924 phase may be performed, directly or indirectly, by an SME, or a software code developer, or both. In various embodiments, performance of the feedback processing operations during the feedback processing 924 phase may result in one or more outputs. In various embodiments, these outputs may include one or more feedback datasets. In these embodiments, the outputs resulting from the performance of a particular mission definition operation, and the method by which it may be produced, is a matter of design choice. In various embodiments, certain outputs of the feedback processing 924 phase may be provided as input data to a simulation 926 phase of the AI campaign lifecycle.

In various embodiments, the simulation 926 phase of the AI campaign lifecycle may include the performance of certain simulation operations. In various embodiments, the simulation operations may include certain operations associated with the setup of certain simulation data 1042, running iterative simulations according to certain parameters 1043, reviewing certain simulation results 1044, and deciding which actions to perform next 1045, or a combination thereof. In various embodiments, the input data used to perform simulation operations in the simulation 926 phase of the AI campaign lifecycle may include data associated with one or more mission definitions, data associated with one or more cohorts, data associated with one or more interventions, or data associated with one or more feedback specifications, or a combination thereof. In these embodiments, the data selected for use in the performance of a particular simulation operation, and the method by which it may be used in the performance of such an operation, is a matter of design choice.

In various embodiments, certain of the simulation operations performed during the simulation 926 phase may be performed, directly or indirectly, by an SME, or a software code developer, or both. In various embodiments, performance of the simulation operations during the simulation 926 phase may result in one or more outputs. In various embodiments, these outputs may include the results of one or more simulations. In these embodiments, the outputs resulting from the performance of a particular simulation operation, and the method by which it may be produced, is a matter of design choice. In various embodiments, certain outputs of the simulation 926 phase may be provided as input data to the mission definition 916 phase of the AI campaign lifecycle.

In various embodiments, the mission definition 916 phase, the intervention definition 922 phase, the feedback processing 924 phase and the simulation 926 phase are configured as a feedback loop. In various embodiments, the feedback loop facilitates training of one or more of the mission definition, the identified cohort and the intervention and the deployable intervention. In various embodiments, one or more of the mission definition operation and the intervention definition operation function as a machine learning operations that use the results of the feedback processing 924 phase and the simulation 926 phase to train one or more of the mission definition, the identified cohort and the intervention and the deployable intervention.

In various embodiments, the KPI definition 920 phase of the AI campaign lifecycle may include the performance of certain KPI definition operations. In various embodiments, the KPI definition operations may include certain operations associated with the identification of one or more KPIs that best aligns with a particular goal 1030, the identification of one or more KPI time horizons and calculation frequencies 1031, determining data availability for a particular KPI 1032, or defining a particular KPI compute algorithm 1033, or a combination thereof. In various embodiments, the input data used to perform KPI definition operations in the KPI definition 920 phase of the AI campaign lifecycle may include data associated with one or more business goals, data associated with one or more business metrics, data associated with one or more business architectures, and data associated with one or more data architectures, or a combination thereof. In these embodiments, the data selected for use in the performance of a particular KPI definition operation, and the method by which it may be used in the performance of such an operation, is a matter of design choice.

In various embodiments, certain of the KPI definition operations performed during the KPI definition 920 phase may be performed, directly or indirectly, by a business owner, a business analyst, an SME, or a combination thereof. In various embodiments, performance of the KPI definition operations during the KPI definition 916 phase may result in one or more outputs. In various embodiments, these outputs may include one or more KPI definitions, one or more KPI dataset specification, one or more KPI checkpoints, or one or more KPI algorithms, or a combination thereof. In these embodiments, the outputs resulting from the performance of a particular KPI definition operation, and the method by which it may be produced, is a matter of design choice. In various embodiments, certain outputs of the KPI definition 920 phase may be provided as input data to a business review and KPI evaluation 928 phase of the AI campaign lifecycle.

In various embodiments, the business review and KPI evaluation 928 phase of the AI campaign lifecycle may include the performance of certain business review and KPI evaluation operations. In various embodiments, the business review and KPI evaluation operations may include certain operations associated with the review of certain KPI trends 1046, reviewing the performance of certain interventions 1047, the review of certain feedback trends 1048, reviewing the responsiveness of certain cohorts 1049, or making certain operational decisions, or a combination thereof. In various embodiments, the input data used to perform business review and KPI evaluation operations in the business review and KPI evaluation 928 phase of the AI campaign lifecycle may include data associated with certain feedback trends, data associated with certain KPI trends, data associated with the performance of certain interventions, or data associated with the behavior of certain cohorts, or a combination thereof. In these embodiments, the data selected for use in the performance of a particular business review and KPI evaluation operation, and the method by which it may be used in the performance of such an operation, is a matter of design choice.

In various embodiments, certain of the business review and KPI evaluation operations performed during the business review and KPI evaluation 928 phase may be performed, directly or indirectly, by a business owner, a business analyst, or an SME, or a or a combination thereof. In various embodiments, performance of the business review and KPI evaluation operations during the business review and KPI evaluation 928 phase may result in one or more outputs. In various embodiments, these outputs may include one or more operational decisions. In these embodiments, the outputs resulting from the performance of a particular business review and KPI evaluation operation, and the method by which it may be produced, is a matter of design choice. In various embodiments, certain outputs of the business review and KPI evaluation 928 phase may be provided as input data to a the mission execution and operational monitoring 930 phase of the AI campaign lifecycle.

In various embodiments, the mission execution and operational monitoring 930 phase of the AI campaign lifecycle may include the performance of certain mission execution and operational monitoring operations. In various embodiments, the mission execution and operational monitoring operations may include certain operations associated with the review of certain system performance metrics 1051, the review of certain system logs 1052, or the identification of certain operational decisions 1053, or a combination thereof. In various embodiments, the input data used to perform mission execution and operational monitoring operations in the mission execution and operational monitoring 930 phase of the AI campaign lifecycle may include data associated with certain monitoring data. In these embodiments, the monitoring data selected for use in the performance of a particular mission execution and operational monitoring operation, and the method by which it may be used in the performance of such an operation, is a matter of design choice.

In various embodiments, certain of the mission execution and operational monitoring operations performed during the mission execution and operational monitoring 930 phase may be performed, directly or indirectly, by a DevOps engineer. In various embodiments, performance of the mission execution and operational monitoring operations during the mission execution and operational monitoring 930 phase may result in one or more outputs. In various embodiments, these outputs may include one or more operational decisions. In these embodiments, the outputs resulting from the performance of a particular mission execution and operational monitoring operation, and the method by which it may be produced, is a matter of design choice. In various embodiments, certain outputs of the mission execution and operational monitoring 930 phase may be provided as feedback data to the business review and KPI evaluation 928 phase of the AI campaign lifecycle.

In certain embodiments, the operations performed in various phases of the AI campaign lifecycle may be performed manually, semi-automatically, or automatically, or a combination thereof. In these embodiments, the determination of which operations may be performed manually, semi-automatically, or automatically, and the method by which they may be performed, is a matter of design choice. Skilled practitioners of the art will recognize that many embodiments of the invention are possible. Accordingly, the foregoing is not intended to limit the spirit, scope, or intent of the invention.

Although the present invention has been described in detail, it should be understood that various changes, substitutions and alterations can be made hereto without departing from the spirit and scope of the invention as defined by the appended claims.

What is claimed is:

1. A computer-implementable method for cognitive information processing, comprising:
receiving data from a plurality of data sources;
processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign;
using the augmented intelligence campaign to generate cognitively processed insights; and,
providing the cognitively processed insights to a destination, the destination comprising a cognitive application, the cognitive application enabling a user to interact with the cognitive insights.

2. The method of claim 1, wherein:
the cognitive process foundation platform comprises a cognitive skill orchestration platform, the cognitive skill orchestration platform being implemented for orchestration of a cognitive skill.

3. The method of claim 1, wherein:
the cognitive process foundation platform comprises a cognitive agent composition platform, the cognitive agent composition platform being implemented for composition of a cognitive agent.

4. The method of claim 1, wherein:
the campaign orchestration platform is implemented to perform a data orchestration operation.

5. The method of claim 1, wherein:
the campaign orchestration platform is implemented to perform a campaign development operation.

6. The method of claim 1, wherein:
the campaign orchestration platform is implemented to perform an agent orchestration operation.

7. A system comprising:
a processor;
a data bus coupled to the processor; and
a non-transitory, computer-readable storage medium embodying computer program code, the non-transitory, computer-readable storage medium being coupled to the data bus, the computer program code interacting with a plurality of computer operations and comprising instructions executable by the processor and configured for:
receiving data from a plurality of data sources;
processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign;
using the augmented intelligence campaign to generate cognitively processed insights; and,
providing the cognitively processed insights to a destination, the destination comprising a cognitive application, the cognitive application enabling a user to interact with the cognitive insights.

8. The system of claim 7, wherein:
the cognitive process foundation platform comprises a cognitive skill orchestration platform, the cognitive skill orchestration platform being implemented for orchestration of a cognitive skill.

9. The system of claim 7, wherein:
the cognitive process foundation platform comprises a cognitive agent composition platform, the cognitive agent composition platform being implemented for composition of a cognitive agent.

10. The system of claim 7, wherein:
the campaign orchestration platform is implemented to perform a data orchestration operation.

11. The system of claim 7, wherein:
the campaign orchestration platform is implemented to perform a campaign development operation.

12. The system of claim 7, wherein:
the campaign orchestration platform is implemented to perform an agent orchestration operation.

13. A non-transitory, computer-readable storage medium embodying computer program code, the computer program code comprising computer executable instructions configured for:
receiving data from a plurality of data sources;
processing the data from the plurality of data sources to provide cognitively processed insights via a augmented intelligence platform, the augmented intelligence platform executing on a hardware processor of an information processing system, the augmented intelligence platform and the information processing system providing a cognitive computing function, the augmented intelligence platform comprising a cognitive process foundation platform, the cognitive process foundation platform comprising a campaign orchestration platform, the campaign orchestration platform being implemented to orchestration an augmented intelligence campaign;
using the augmented intelligence campaign to generate cognitively processed insights; and,
providing the cognitively processed insights to a destination, the destination comprising a cognitive application, the cognitive application enabling a user to interact with the cognitive insights.

14. The non-transitory, computer-readable storage medium of claim 13, wherein:
the cognitive process foundation platform comprises a cognitive skill orchestration platform, the cognitive skill orchestration platform being implemented for orchestration of a cognitive skill.

15. The non-transitory, computer-readable storage medium of claim 13, wherein:
the cognitive process foundation platform comprises a cognitive agent composition platform, the cognitive agent composition platform being implemented for composition of a cognitive agent.

16. The non-transitory, computer-readable storage medium of claim 13, wherein:
the campaign orchestration platform is implemented to perform a data orchestration operation.

17. The non-transitory, computer-readable storage medium of claim 16, wherein:
the campaign orchestration platform is implemented to perform a campaign development operation.

18. The non-transitory, computer-readable storage medium of claim 13, wherein:
the campaign orchestration platform is implemented to perform an agent orchestration operation.

19. The non-transitory, computer-readable storage medium of claim 13, wherein:
the computer executable instructions are deployable to a client system from a server system at a remote location.

20. The non-transitory, computer-readable storage medium of claim 13, wherein:
the computer executable instructions are provided by a service provider to a user on an on-demand basis.
